(19) United States
(12) Patent Application Publication
(10) Pub. No.: US 2025/0070084 A1
(43) Pub. Date: Feb. 27, 2025

(54) PACKAGE STRUCTURE INCLUDING PACKAGE LID WITH A RECESS AND METHODS OF FORMING THE SAME

(71) Applicant: Taiwan Semiconductor Manufacturing Company Limited, Hsinchu (TW)

(72) Inventors: Tsung-Yen Lee, Hemei Township (TW); Chia-Kuei Hsu, Hsinchu City (TW); Ming-Chih Yew, Hsinchu City (TW); Shin-Puu Jeng, Po-Shan Village (TW)

(21) Appl. No.: 18/455,698

(22) Filed: Aug. 25, 2023

(51) Int. Cl. H01L 25/065; H01L 21/56; H01L 23/00; H01L 23/31; H01L 23/498

(52) U.S. Cl. CPC H01L 25/0655; H01L 21/565; H01L 23/3107; H01L 23/49822; H01L 24/08; H01L 24/16; H01L 24/32; H01L 24/73; H01L 24/83; H01L 2224/08238; H01L 2224/16227; H01L 2224/16238; H01L 2224/32225; H01L 2224/32245; H01L 2224/73204; H01L 2224/73253; H01L 2224/80895; H01L 2224/80896; H01L 2224/83203; H01L 2924/16151; H01L 2924/1616; H01L 2924/16235; H01L 2924/16251

(57) ABSTRACT

A package structure includes a package substrate, a semiconductor module on the package substrate and including a semiconductor module corner portion, and a package lid on the package substrate and over the semiconductor module, the package lid including a package lid foot portion attached to the package substrate, and a package lid plate portion attached to the package lid foot portion and over the semiconductor module, wherein the package lid plate portion includes a recess over the semiconductor module corner portion.

### BACKGROUND

A package structure (e.g., semiconductor package) may include one or more semiconductor dies (e.g., semiconductor devices) on a package substrate, and a package lid covering the one or more semiconductor dies. The package lid may help to ensure the reliability, performance, and longevity of the package structure.

In particular, the package lid may provide a protective barrier against external environmental factors such as dust, moisture, and contaminants. The package lid may also provide mechanical strength to the package structure, making it more resistant to physical stress, vibrations, and impact. The package lid may also serve as a heat spreader, transferring heat away from the package structure to the surrounding environment or to a heat sink. The package lid may also serve as an electromagnetic interference (EMI) shield that reduces the impact of external electromagnetic fields on the internal circuitry. The package lid may also provide a hermetic seal to prevent the ingress of moisture or gases that could degrade the performance or reliability of the package structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to one or more embodiments.

FIG. 1B is a plan view (e.g., top-down view) of the package structure according to one or more embodiments.

FIG. 1C is a plan enlarged view of a portion of the package structure including a recess in the package lid plate portion according to one or more embodiments.

FIG. 2A is a perspective view of the package lid including the recesses in the package lid plate portion according to one or more embodiments.

FIG. 2B is a vertical cross-sectional enlarged view of a portion of the package lid plate portion including a recess according to one or more embodiments.

FIG. 3A is a vertical cross-sectional view of an intermediate structure including the semiconductor material layer according to one or more embodiments.

FIG. 3B is a vertical cross-sectional view of an intermediate structure including the TSVs in the semiconductor material layer according to one or more embodiments.

FIG. 3C is a vertical cross-sectional view of an intermediate structure including the bonding layer and upper bonding pads according to one or more embodiments.

FIG. 3D is a vertical cross-sectional view of an intermediate structure including the semiconductor die according to one or more embodiments.

FIG. 3E is a vertical cross-sectional view of an intermediate structure including the molding material layer according to one or more embodiments.

FIG. 3F is a vertical cross-sectional view of an intermediate structure after the thinning (e.g., planarizing) of the semiconductor material layer and forming the C4 bumps according to one or more embodiments.

FIG. 4 is a flow chart illustrating a method of forming a semiconductor module according to one or more embodiments.

FIG. 5A is a vertical cross-sectional view of an intermediate structure including the package substrate having package substrate upper bonding pads and package substrate lower bonding pads, according to one or more embodiments.

FIG. 5B illustrates a vertical cross-sectional view of an intermediate structure in which the semiconductor module may be attached to the package substrate, according to one or more embodiments.

FIG. 5C illustrates a vertical cross-sectional view of an intermediate structure in which the package underfill layer may be formed on the package substrate according to one or more embodiments.

FIG. 5D illustrates a vertical cross-sectional view of an intermediate structure in which the optional adjacent dies may be mounted on the package substrate according to one or more embodiments.

FIG. 5E illustrates a vertical cross-sectional view of an intermediate structure including the TIM layer and the TIM layer according to one or more embodiments.

FIG. 5F illustrates a vertical cross-sectional view of an intermediate structure in which the adhesive layer may be applied to the package substrate according to one or more embodiments.

FIG. 5G illustrates a vertical cross-sectional view of an intermediate structure in which the package lid may be attached to (e.g., mounted on) the package substrate according to one or more embodiments.

FIG. 5H illustrates a vertical cross-sectional view of an intermediate structure in which a plurality of solder balls may be formed on the package substrate according to one or more embodiments.

FIG. 6 is a flow chart illustrating a method of forming a package structure according to one or more embodiments.

FIG. 7A is a plan view of a recess having a first alternative design according to one or more embodiments.

FIG. 7B is a plan view of recess having a second alternative design according to one or more embodiments.

FIG. 7C is a plan view of recess having a third alternative design according to one or more embodiments.

FIG. 8 is a perspective view of the package lid including a recess having a fourth alternative design according to one or more embodiments.

FIG. 9 is a vertical cross-sectional view of the package structure having a first alternative design according to one or more embodiments.

FIG. 10 is a vertical cross-sectional view of the package structure having a second alternative design according to one or more embodiments.

FIG. 11 is a vertical cross-sectional view of the package structure having a third alternative design according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

In embodiments in which a package lid is used over an interposer (e.g., silicon interposer) in the package structure, there is a possibility of inducing stress on the interposer. This stress may be due to several factors. For example, the stress may be due to thermal expansion mismatch. Package lids may be made of materials such as metal alloys or ceramics having a different coefficient of thermal expansion (CTE) as compared to the interposer. During operation, heat generated by the semiconductor die(s) in the package structure may cause a temperature of the interposer and a temperature of the package lid to rise. The difference in CTEs may cause the interposer and package lid to expand at different rates. This difference in thermal expansion may create stress on the interposer, especially at the interfaces between the interposer and the lid or the interposer and the semiconductor die(s). In particular, an expansion of the package lid may induce a stress concentrated in the interposer at a corner of the semiconductor die. Expansion of the package lid may also be a driving force inducing high stress in a hybrid bond formed between a semiconductor die (e.g., top die) and an interposer in a semiconductor module.

The stress on the interposer may also be due to a mechanical constraint in the package structure. That is, in instances in which the package lid is bonded to the package substrate or interposer (e.g., using adhesive materials or solder), the bonding process and the subsequent cooling may create a mechanical constraint on the interposer. In instances in which the package lid and the interposer have different mechanical properties, such as stiffness or elasticity, such differences in mechanical properties may lead to stress concentration points and induce mechanical stress on the interposer.

The stress on the interposer may also occur during the manufacture of the package structure (e.g., the packaging process). The assembly process of attaching the package lid to the package substrate, for example, may involve various steps including heating, cooling, and mechanical handling. These steps may introduce mechanical stress on the interposer, especially in instances in which there is inadequate support or improper alignment during attachment of the package lid. Improper handling or excessive force during the packaging process may also cause deformation or misalignment, resulting in stress on the interposer.

The induced stress on the interposer due to the package lid may have a variety of consequences. In particular, the stress may lead to mechanical failure in the interposer, such as cracking or delamination. The stress may also lead to deformation of the interposer, which may alter the electrical properties of the interposer. This may in turn impact signal transmission, power distribution, and overall device performance. The stress may also reduce a resistance of the interposer to fatigue or aging, potentially leading to long-term reliability concerns.

One or more embodiments of the present disclosure may include a package lid having one or more recesses (e.g., a recessed portion such as a lid cave, stress relief cave, etc.). The recess may be located in the package lid at a corner of a semiconductor die on the interposer. The one or more embodiments may help to improve (e.g., optimize) a structure of the package lid so as to reduce a stress concentration in the interposer.

The package structure may include, for example, a package substrate, a semiconductor module on the package substrate, and a package lid (e.g., stiffener, ring, etc.) over the semiconductor module and attached to the package substrate by an adhesive material (e.g., stiffener adhesive material). The package structure may integrate homogeneous or heterogeneous components (e.g., semiconductor dies). In particular, the homogeneous or heterogeneous components may be connected through the interposer.

The semiconductor module may include two or more semiconductor dies (e.g., components, system on chip die, application-specific integrated circuit (ASIC) die, etc.) on an interposer (e.g., silicon interposer). The semiconductor dies (e.g., top dies) may be attached to the interposer by a hybrid bond. The package lid may include one or more of the recesses at a corner of one or more of the semiconductor dies to reduce a stress concentration in the interposer. In at least one embodiment, the recesses in the package lid may reduce a stress in a hybrid bond between the semiconductor dies and the interposer.

The semiconductor module may be attached to the package substrate by a plurality of C4 bumps and package underfill (e.g., C4 underfill) may be formed on the package substrate around the C4 bumps. The package structure may also include molding material around the semiconductor dies, and a thermal interface material (TIM) film between the package lid and the semiconductor dies and molding material.

The package structure may also include one or more adjacent dies (e.g., silicon dies, memory dies (e.g., dynamic random access memory (DRAM) dies, etc.) on the package substrate adjacent the semiconductor module. The adjacent dies may be attached to the package substrate (e.g., directly attached to the package substrate) by additional C4 bumps. Additional package underfill may be formed on the package substrate around the additional C4 bumps.

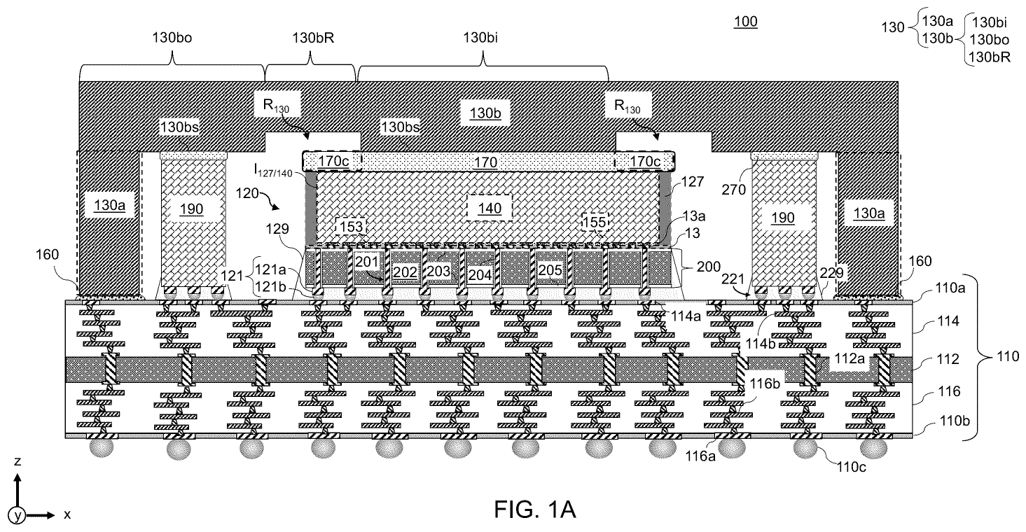

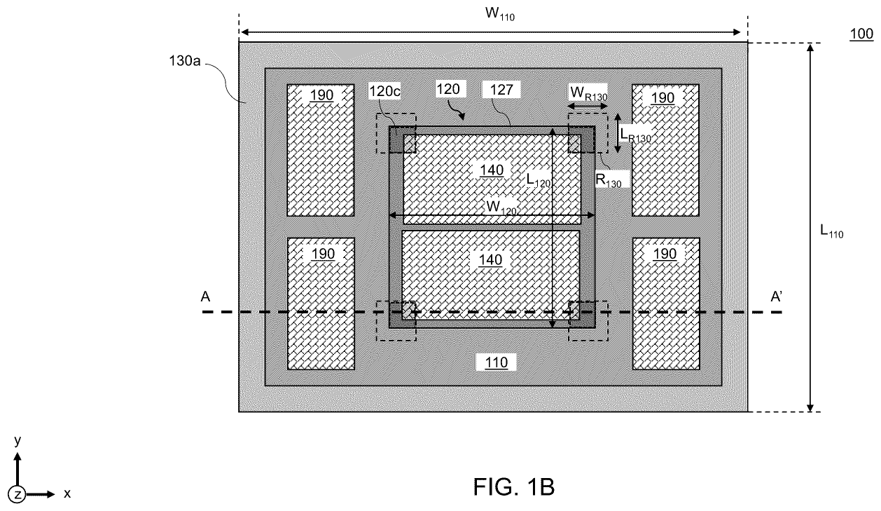

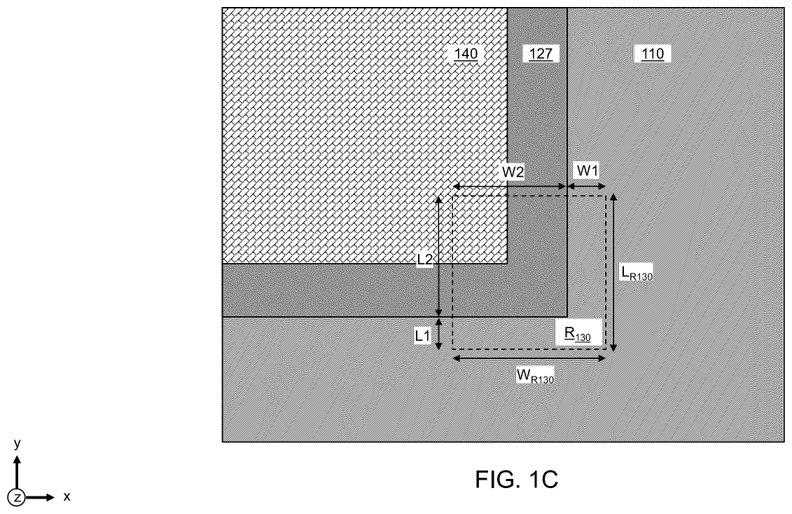

FIG. 1A is a vertical cross-sectional view of a package structure 100 according to one or more embodiments. FIG. 1B is a plan view (e.g., top-down view) of the package structure 100 according to one or more embodiments. The vertical cross-sectional view in FIG. 1A is along the line A-A′ in FIG. 1B. FIG. 1C is a plan view of a portion of the package structure 100 including a recess R₁₃₀ in the package lid plate portion 130b according to one or more embodiments.

Generally, the package structure 100 may include a package substrate 110 and a semiconductor module 120 on the package substrate 110. The package structure 100 may also include a package lid 130 on the package substrate 110 and over the semiconductor module 120. The package lid 130 may include a package lid foot portion 130a attached to the package substrate 110, and a package lid plate portion 130b attached to the package lid foot portion 130a and over the semiconductor module 120. The package lid plate portion 130b may include one or more recesses R₁₃₀ over a semiconductor module corner portion of the semiconductor module 120.

Referring to FIG. 1A, the package substrate 110 may include, for example, a cored package substrate. In particular, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). The package structure 100 may alternatively include a coreless package substrate instead of a cored package substrate. In at least one embodiment, the package substrate 110 may include a build-up film substrate such as an Ajinomoto build-up film (ABF) substrate. In that case, the package substrate 110 may be described as an ABF substrate.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. An insulating liner (not shown) such as a silicon oxide liner may also be formed around the through vias 112a in the core 112.

The package substrate upper dielectric layer 114 may be formed on an upper surface of the core 112. The package substrate upper dielectric layer 114 may include a plurality of layers and, in particular, may include an Ajinomoto build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate 110 (e.g., a chip-side surface of the package substrate upper dielectric layer 114). The package substrate upper bonding pads 114a may be exposed on the chip-side surface of the package substrate 110. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

An upper passivation layer 110a may be formed on the chip-side surface of the package substrate 110. The upper passivation layer 110a may partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate 110 (e.g., a board-side surface of the package substrate lower dielectric layer 116). The package substrate lower bonding pads 116a may be exposed on the board-side surface of the package substrate 110. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate upper bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 110b may be formed on the board-side surface of the package substrate 110. The lower passivation layer 110b may partially cover the package substrate lower bonding pads 116a. The lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

In at least one embodiment, the package substrate lower dielectric layer 116 may also include one or more package substrate dummy vias (not shown). The package substrate dummy vias may provide rigidity to the package substrate 110. The package substrate dummy vias may be formed, for example, in the board-side surface of the package substrate 110 and may or may not be exposed at the board-side surface of the package substrate 110. The package substrate dummy vias may be substantially aligned with an inner edge of the package lid foot portion 130a. In particular, a centerline in the x-direction of the package substrate dummy vias may be substantially aligned with the inner edge of the package lid foot portion 130a.

A ball-grid array (BGA) including a plurality of solder balls 110c may be formed on the board-side surface of the package substrate 110. The solder balls 110c may allow the package structure 100 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b. The solder balls 110c of the BGA may be formed in a two-dimensional array on the board-side surface of the package substrate 110. The solder balls 110c may be located, for example, under the package lid foot portion 130a and under the semiconductor module 120.

Referring again to FIG. 1A, the semiconductor module 120 may be located in a central portion of the package substrate 110. The semiconductor module 120 may include an interposer 200 and a plurality of semiconductor dies 140 (e.g., FIG. 1B) on the interposer 200. The semiconductor module 120 may be attached by C4 bumps 121 to the package substrate upper bonding pads 114a in the package substrate 110. The C4 bumps 121 may include a metal pillar 121a (e.g., copper pillar) and a solder bump 121b (e.g., SnAg solder bump) on the metal pillar 121a. The solder bump 121b of the C4 bump 121 may be collapsed to join the metal pillar 121a of the C4 bump 121 to the package substrate upper bonding pads 114a.

A package underfill layer 129 may be formed on the package substrate 110, under and around the semiconductor module 120 and around the C4 bumps 121. The package underfill layer 129 may help to securely fix the semiconductor module 120 to the package substrate 110. The package underfill layer 129 may be formed of an epoxy-based polymeric material.

The interposer 200 of the semiconductor module 120 may include an inorganic interposer. The interposer 200 may include a semiconductor material layer 202. In at least one embodiment, the semiconductor material layer 202 may include a silicon-based semiconductor material. The semiconductor material layer 202 may include single crystalline silicon or polycrystalline silicon. The semiconductor material layer 202 may be undoped or doped with electrical dopants such as p-type dopants or n-type dopants.

The interposer 200 may include a plurality of via cavities 201 in the semiconductor material layer 202. The via cavities 201 may extend in the z-direction through an entire thickness of the semiconductor material layer 202. A lateral dimension (such as the diameter) of the via cavities 201 may be in a range from 0.5 micron to 10 microns, such as from 1 micron to 6 microns, although lesser and greater lateral dimensions may also be used. In one embodiment, the pattern of the array of via cavities 201 may have a two-dimensional periodicity over the interposer 200.

An insulating liner 203 may be formed in peripheral portions of the via cavities 201 and on an upper surface of the semiconductor material layer 202. The insulating liner 203 may include, for example, silicon oxide, silicon nitride, low-k dielectric materials such as carbon-doped oxides, extremely low-k dielectric materials such as porous carbon doped silicon dioxide, a combination thereof or other suitable material. The insulating liner 203 may have a thickness in a range from 1% to 20%, such as from 2% to 5% of the lateral dimension of the via cavities 201.

A plurality of through silicon vias (TSVs) 204 may be located in the plurality of via cavities 201, respectively. The TSVs 204 may include at least one conductive material, such as at least one metallic material, in a central portion of the via cavities 201. The TSVs 204 and the front insulating liner 203 may substantially fill the via cavities 201. The TSVs 204 may include, for example, a combination of a metallic barrier material (such as TiN, TaN, WN, MON, TiC, TaC, WC, etc.) and a metallic fill material (such as Cu, Co, Ru, Mo, W, etc.). Other suitable metallic barrier materials and metallic fill materials are within the contemplated scope of disclosure.

The interposer 200 may also include a lower insulating layer 205 on a bottom surface of the semiconductor material layer 202. The lower insulating layer 205 may join the insulating liner 203 in the via cavities 201. The lower insulating layer 205 may include a material that is the same or similar to the material of the insulating liner 203. The lower insulating layer 205 may include, for example, silicon oxide, silicon nitride, low-k dielectric materials such as carbon-doped oxides, extremely low-k dielectric materials such as porous carbon doped silicon dioxide, a combination thereof or other suitable material.

As illustrated in FIG. 1A, the plurality of C4 bumps 121 may be connected to the TSVs 204 on the board-side surface of the interposer 200, respectively. The metal pillars 121a of the C4 bumps 121 may be located at least partially on the lower insulating layer 205. The lower insulating layer 205 may serve to electrically insulate the C4 bumps 121 from the semiconductor material layer 202.

Referring again to FIG. 1A, the semiconductor module 120 may further include a bonding layer 13 on an upper surface (e.g., chip-side surface) of the interposer 200. The bonding layer 13 may include a dielectric material such as silicon oxide, low-k dielectric materials such as carbon-doped oxides, extremely low-k dielectric materials such as porous carbon doped silicon dioxide, a combination thereof or other suitable materials.

One or more upper bonding pads 13a may be formed in the bonding layer 13 on the upper surface of the interposer 200. The bonding layer 13 may at least partially cover the upper bonding pads 13a. That is, the upper bonding pads 13a may be at least partially exposed on the upper surface of the interposer 200. The upper bonding pads 13a may be connected (e.g., electrically coupled) to the TSVs 204 in the interposer 200. The upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. In at least one embodiment, a material of the upper bonding pads 13a may be the same as a material of the TSVs 204 in the interposer 200.

The semiconductor dies 140 may be attached to (e.g., mounted on) the upper surface of the interposer 200 through the bonding layer 13 and the upper bonding pads 13a. In particular, the semiconductor dies 140 may be flip-chip mounted on the upper surface of the interposer 200. That is, an active region of the semiconductor dies 140 may face the interposer 200 and a bulk semiconductor region of the semiconductor dies 140 may be opposite the active region. The upper surfaces of the semiconductor dies 140 (e.g., upper surface of the bulk semiconductor region) may be substantially coplanar. In particular, the upper surfaces of the semiconductor dies 140 may be located at a same height measured from an upper surface of the bonding layer 13.

The semiconductor dies 140 may include a die bonding layer 153 on the active region side of the semiconductor dies 140. The die bonding layer 153 may include a dielectric material such as silicon oxide, low-k dielectric materials such as carbon-doped oxides, extremely low-k dielectric materials such as porous carbon doped silicon dioxide, a combination thereof or other suitable material. The semiconductor dies 140 may also include one or more die bonding pads 155 in the die bonding layer 153. The die bonding pads 155 may be at least partially exposed through the die bonding layer 153.

The semiconductor dies 140 may be bonded to the interposer 200 by a hybrid bond which may also be known as direct bonding or wafer-to-wafer bonding. The hybrid bond may include a metallic portion and a dielectric portion. In at least one embodiment, the hybrid bond may include a metal-metal bond and an oxide-oxide bond. In particular, the hybrid bond may include a bond between the die bonding pads 155 and the upper bonding pads 13a, and a bond between the die bonding layer 153 and the bonding layer 13 (e.g., oxide layer) of the interposer 200. The hybrid bond may enable high-density interconnects and efficient signal transfer between the semiconductor dies 140 and the interposer 200.

Each of the semiconductor dies 140 may include, for example, a singular semiconductor die, a system on chip die, or a system on integrated chips die. Each of the semiconductor dies 140 may be implemented by chip on wafer on substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide input/output (I/O) die, a M-RAM die, a R-RAM die, a NAND die, static random access memory (SRAM) die, etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc.

In at least one embodiment, the semiconductor dies 140 may include a primary die and an ancillary die that may support an operation of the primary die. In at least one embodiment, the primary die may include a system on chip die and the ancillary die may include a memory die (e.g., DRAM die, HBM die, etc.).

The semiconductor module 120 may also include a molding material layer 127 on the interposer 200, on and around the semiconductor dies 140 and between the semiconductor dies 140. The molding material layer 127 may be formed on (e.g., cover) and bonded to one or more sidewalls (e.g., all of the sidewalls) of the semiconductor dies 140. In at least one embodiment, the semiconductor dies 140 may be substantially “embedded” within the molding material layer 127. The molding material layer 127 may also be formed on and bonded to a surface of the bonding layer 13. The molding material layer 127 may also be formed on and bonded to a surface of the interposer 200.

In at least one embodiment, the molding material layer 127 may contact a sidewall of the semiconductor dies 140 so that at least a portion of the sidewall may constitute a die/molding material interface I_{127/140}. The die/molding material interface I_{127/140} may be formed, for example, around an entire periphery of the semiconductor die 140. The die/molding material interface I_{127/140} may be formed laterally around one or more of the sidewalls of the semiconductor die 140. That is, the die/molding material interface I_{127/140} may wrap around an entirety of the semiconductor die 140 in the x and y directions. The die/molding material interface I_{127/140} may also extend in the z-direction across an entirety of the semiconductor die 140. In at least one embodiment, the die/molding material interface I_{127/140} may extend in the z-direction from a bottom of the die bonding layer 153 (which may contact the bonding layer 13 of the interposer 200) to an upper surface of the semiconductor die 140.

An upper surface of the molding material layer 127 may be substantially uniform (e.g., flat). The upper surface may also be substantially coplanar with the upper surface of the semiconductor dies 140. An outer sidewall of the molding material layer 127 may be substantially aligned with an outer sidewall of the interposer 200. In at least one embodiment, an outer sidewall of the semiconductor module 120 may be constituted at least in part by the outer sidewall of the molding material layer 127, at least in part by the outer sidewall of the bonding layer 13 and at least in part by the outer sidewall of the interposer 200.

In at least one embodiment, the molding material layer 127 may be formed of a curable material that may cure to form a hard, solid structure. The molding material layer 127 may include, for example, epoxy molding compound (EMC). In at least one embodiment, the molding material layer 127 may include a polymeric material and in particular, an epoxy-based polymeric material. Other suitable molding materials may be used.

In at least one embodiment, the molding material layer 127 may have a CTE that is substantially similar to a CTE of the interposer 200. In at least one embodiment, the molding material layer 127 may include an added material (e.g., filler material) for improving a property of the molding material layer 127 (e.g., thermal conductivity, CTE, etc.). The added material may include, for example, metal powder, metal oxide powder, etc. Other materials in the molding material layer 127 are within the contemplated scope of the disclosure.

A thermal interface material (TIM) layer 170 may be included in the package structure 100 to help dissipate heat. The TIM layer 170 may be located on the upper surface of the semiconductor module 120. In at least one embodiment, a center of the TIM layer 170 may be substantially aligned with a center of the semiconductor module 120. The TIM layer 170 may have a low bulk thermal impedance and high thermal conductivity. The bond-line-thickness (BLT) (e.g., a distance between the package lid 130 and the semiconductor module 120) may be less than about or equal to about 500 μm, although greater or lesser distances may be used. In at least one embodiment, a thickness of the TIM layer 170 may be less than or equal to about 500 μm. The TIM layer 170 may cover an entire area of the upper surface of the semiconductor module 120. The TIM layer 170 may be attached to the upper surface of the semiconductor module 120 by a thermally conductive adhesive. The TIM layer 170 may contact, for example, the upper surface of the semiconductor dies 140 and the upper surface of the molding material layer 127.

The TIM layer 170 may include, for example, a thermal paste, thermal adhesive, thermal gap filler, thermal pad (e.g., silicone), thermal tape or a gel TIM (e.g., a cross-linked polymer film). The TIM layer 170 may include one or more materials having a high thermal conductivity. In at least one embodiment, the TIM layer 170 may include graphite, carbon nanotubes (CNTs), etc. Other types of materials for the TIM layer 170 are within the contemplated scope of this disclosure.

Referring again to FIG. 1A, the package structure 100 may optionally include one or more adjacent dies 190 on the package substrate 110. The adjacent dies 190 may be located (at least in part) between the semiconductor module 120 and the package lid foot portion 130a. The adjacent dies 190 may include, for example, a semiconductor die such as the semiconductor dies 140 described above. In at least one embodiment, the adjacent dies 190 may include a memory die such as a DRAM die, HBM die, etc. The adjacent dies 190 may be electrically coupled to the semiconductor module 120 (and the semiconductor dies 140 in the semiconductor module 120) through the package substrate 110. The adjacent dies 190 may also include non-functional dies (e.g., dummy dies) that may provide structural support to the package structure 100.

The adjacent dies 190 may be attached to the package substrate 110 by a plurality of C4 bumps 221. The C4 bumps 221 may have a structure and function substantially similar to the structure and function of the C4 bumps 121 described above. Similar to the C4 bumps 121, the C4 bumps 221 may be bonded the package substrate upper bonding pads 114a, respectively. The adjacent dies 190 may be electrically coupled to the package substrate 110 through the C4 bumps 221. Other suitable means of attaching the adjacent dies 190 to the package substrate 110 (e.g., adhesive) may be used.

An underfill layer 229 may be formed on the package substrate 110 under and around the adjacent dies 190 and around the C4 bumps 221. The underfill layer 229 may help to securely fix the adjacent dies 190 to the package substrate 110. The underfill layer 229 may be substantially the same as the package underfill layer 129 described above. In particular, the underfill layer 229 may be formed of an epoxy-based polymeric material.

An adjacent TIM layer 270 may be located on the adjacent dies 190. The adjacent TIM layer 270 may help to dissipate heat generated in the adjacent dies 190. The adjacent TIM layer 270 may contact an upper surface of the adjacent dies 190. The adjacent TIM layer 270 may have a structure and function substantially similar to the structure and function of the TIM layer 170 described above. As illustrated in FIG. 1A, a height in the z-direction of the upper surface of the adjacent dies 190 (e.g., measured from the upper surface of the package substrate 110) may be greater than a height of the upper surface of the semiconductor module 120. In such embodiments, a thickness of the adjacent TIM layer 270 may be less than a thickness of the TIM layer 170 by an amount corresponding to the height difference.

Referring again to FIG. 1A, the package lid 130 may be located on the TIM layer 170 (and optional adjacent TIM layer 270) and may provide a cover for the semiconductor module 120. The package lid 130 may also be located on the adjacent TIM layer 270 and may provide a cover for the adjacent dies 190. The package lid 130 may be formed, for example, of metal, ceramic or polymer material. Other suitable materials of the package lid 130 may be used.

The package lid foot portion 130a of the package lid 130 may be attached to the package substrate 110. The package lid foot portion 130b may extend in a substantially perpendicular direction from the package lid plate portion 130b. The package lid foot portion 130b may be connected to the package substrate 110 by an adhesive 160. The adhesive 160 may include, for example, epoxy adhesive or silicone adhesive. Other adhesives are within the contemplated scope of this disclosure.

The package lid plate portion 130b (e.g., main body of the package lid 130) may be connected to the package lid foot portion 130a (e.g., an upper end of the package lid foot portion 130a). An outer periphery of the package lid plate portion 130b may be substantially aligned with an outer periphery of the package lid foot portion 130a. In at least one embodiment, the package lid plate portion 130b may be attached to the package lid foot portion 130a by an adhesive (not shown). The adhesive may be substantially similar to the adhesive 160 described above. In at least one embodiment, the package lid plate portion 130b may be integrally formed as a unit with the package lid foot portion 130a.

The package lid plate portion 130b may have a plate-shape extending, for example, in an x-y plane in FIG. 1A. The package lid plate portion 130b may be substantially parallel to an upper surface of the package substrate 110. The package lid plate portion 130b may include an inner region 130bi that is formed over a central portion of the semiconductor module 120. The inner region 130bi may contact at least a portion of the TIM layer 170 over the central portion of the semiconductor module 120. In at least one embodiment, a center of the inner region 130bi may be substantially aligned with the center of the semiconductor module 120 and/or with the center of the TIM layer 170.

The package lid plate portion 130b may include a bottom surface 130bs. The bottom surface 130bs may extend across an underside of the package lid plate portion 130b. In at least one embodiment, the bottom surface 130bs may extend between the package lid foot portion 130a on one side of package structure 100 to the package lid foot portion 130a on the opposite side of the package structure 100. In at least one embodiment, the bottom surface 130bs may constitute substantially the entire underside of the package lid plate portion 130b outside of the recesses R₁₃₀. The bottom surface 130bs of the inner region 130bi of the package lid plate portion 130b may contact the TIM layer 170. In one or more embodiments, an entirety of the bottom surface 130bs of the inner region 130bi of the package lid plate portion 130b may directly contact the upper surface of the TIM layer 170. Further, in one or more embodiments, the TIM layer 170 may be compressed between the upper surface of the semiconductor module 120 and the bottom surface 130bs of the inner region 130bi of the package lid plate portion 130b.

As illustrated in FIG. 1A, the one or more recesses R₁₃₀ may be located in the bottom surface 130bs of the package lid plate portion 130b. The recesses R₁₃₀ may be located over a TIM layer corner portion 170c of the TIM layer 170. An upper surface of the TIM layer corner portion 170c may be substantially coplanar with the bottom surface 130bs of the package lid plate portion 130b. In at least one embodiment, a height of the upper surface of the TIM layer corner portion 170c may be greater than a height of the bottom surface 130bs of the package lid plate portion 130b, so that the TIM layer corner portion 170c protrudes slightly into the recesses R₁₃₀. At least a portion of the recess R₁₃₀ may be located over the semiconductor module 120 under the TIM layer corner portion 170c.

The package lid plate portion 130b may include a recess region 130bR located over the recess R₁₃₀ in the bottom surface 130bs of the package lid plate portion 130b. A thickness of the recess region 130bR of the package lid plate portion 130b may be less than a thickness of the inner region 130bi of the package lid plate portion 130b.

The package lid plate portion 130b may also include an outer region 130bo that is outside the recess region 130bR and outside the inner region 130bi. A thickness of the outer region 130bo of the package lid plate portion 130b may be substantially the same as a thickness of the inner region 130bi of the package lid plate portion 130b and greater than a thickness of the recess region 130bR of the package lid plate portion 130b.

The outer region 130bo may be located over the adjacent dies 190. The bottom surface 130bs of the outer region 130bo of the package lid plate portion 130b may contact the adjacent TIM layer 270. In one or more embodiments, the bottom surface 130bs of the outer region 130bo of the package lid plate portion 130b may directly contact an entire upper surface of the adjacent TIM layer 270. In one or more embodiments, the adjacent TIM layer 270 may be compressed between the upper surface of the adjacent dies 190 and the bottom surface 130bs of the outer region 130bo of the package lid plate portion 130b.

Referring to FIG. 1B, the package lid plate portion 130b and the TIM layer 170 are omitted from FIG. 1B for ease of understanding. Thus, the view in FIG. 1B is looking down into the package structure 100 from above. As illustrated in FIG. 1B, the package lid foot portion 130a (and thus, the package lid plate portion 130b (not shown)) may have an outer shape that is substantially the same as an outer shape of the package substrate 110. Further, the semiconductor module 120 may be arranged in a central portion of the package substrate 110, and the adjacent dies 190 may be arranged around the semiconductor module 120. Although FIG. 1B illustrates the package structure 100 as including four adjacent dies 190 having a particular arrangement, the number of adjacent dies 190 and the arrangement of the adjacent dies 190 is not limited to the number and arrangement in FIG. 1B. The adjacent dies 190 may have a width in the x-direction (first direction) and a length greater than the width in the y-direction (second direction). In at least one embodiment, a first pair of the adjacent dies 190 may be aligned in the y-direction on one side of the semiconductor module 120 and a second pair of the adjacent dies 190 may be aligned in the y-direction on another side of the semiconductor module 120 opposite the first pair of adjacent dies 190.

In at least one embodiment, the package substrate 110 may have a width W₁₁₀ in the x-direction and a length L₁₁₀ less than the width W₁₁₀ in the y-direction. The package lid foot portion 130a (and the package lid plate portion 130b) may have a width and length substantially similar (e.g., slightly less) that the width W₁₁₀ and length L₁₁₀ of the package substrate 110, respectively.

The semiconductor module 120 may have a width W₁₂₀ in the x-direction and a length L₁₂₀ in the y-direction. The semiconductor module 120 may have a substantially square shape (e.g., L₁₂₀=W₁₂₀) or rectangular shape (e.g., L₁₂₀<W₁₂₀). Other shapes of the semiconductor module 120 are within the contemplated scope disclosure. The semiconductor dies 140 may have a length in the x-direction and a width less than the length in the y-direction. Although the semiconductor module 120 is illustrated in FIG. 1B as including two semiconductor dies 140 having a particular arrangement, the number of semiconductor dies 140 and the arrangement of the semiconductor dies 140 is not limited to the number and arrangement in FIG. 1B.

Locations of the recesses R₁₃₀ in the package lid plate portion 130b are also illustrated in FIG. 1B for ease of understanding. The recesses R₁₃₀ may be located over a semiconductor module corner portion 120c of the semiconductor module 120. As illustrated in FIG. 1B, the semiconductor module corner portion 120c may include a corner of the semiconductor die 140 and a corner of the molding material layer 127. The semiconductor module 120 may include four (4) semiconductor module corner portions 120c and the recesses R₁₃₀ may be located over all four (4) of the semiconductor module corner portions 120c. In at least one embodiment, the recesses R₁₃₀ may be located over less than all of the semiconductor module corner portions 120c of the semiconductor module 120.

The TIM layer 170 may have an outline that is substantially the same as the outline of the semiconductor module 120. Thus, the recesses R₁₃₀ may be located over the TIM layer corner portions 170c that is over the semiconductor module corner portions 120c. The recesses R₁₃₀ may include a portion over the semiconductor die 140, a portion over the molding material layer 127 and a portion over package substrate 110. In at least one embodiment, the package underfill layer 129 (not shown in FIG. 1B) may include an outer portion that is outside the molding material layer 127, in which case, the recesses R₁₃₀ may include a portion over the outer portion of the package underfill layer 129.

The recess R₁₃₀ may have a recess width W_{R130} in the x-direction and a recess length L_{R130} in the y-direction. In at least one embodiment, the recess width W_{R130} of the recess R₁₃₀ may be substantially equal to the recess length L_{R130} of the recess R₁₃₀ (e.g., W_{R130}=L_{R130}). The recess width W_{R130} of the recess R₁₃₀ may alternatively be greater than the recess length L_{R130} of the recess R₁₃₀ (e.g., W_{R130}>L_{R130}). The recess width W_{R130} of the recess R₁₃₀ may alternatively be less than the recess length L_{R130} of the recess R₁₃₀ (e.g., W_{R130}<L_{R130}).

Referring to FIG. 1C, the recess width W_{R130} of the recess R₁₃₀ may include a first width portion W₁ outside the semiconductor module 120 (e.g., over the package substrate 110 and/or the outer portion of the package underfill layer 129 (not shown)). The recess width W_{R130} of the recess R₁₃₀ may also include a second width portion W₂ over the semiconductor module 120 (e.g., over the semiconductor die 140 and the molding material layer 127). In at least one embodiment, the recess width W_{R130} may be the sum of the first width portion W₁ and the second width portion W₂ (e.g., W_{R130}=W₁+W₂).

In at least one embodiment (e.g., where the recess R₁₃₀ has an irregular shape), the first width portion W₁ may be a maximum distance from an edge of the recess R₁₃₀ (outside the semiconductor module 120) perpendicular to a side of the semiconductor module 120 in the x-direction. The second width portion W₂ may be a maximum distance from an edge of the recess R₁₃₀ (over the semiconductor module 120) perpendicular to a side of the semiconductor module 120 in the x-direction.

The recess length L_{R130} of the recess R₁₃₀ may include a first length portion L1 outside the semiconductor module 120 (e.g., over the package substrate 110 and/or the outer portion of the package underfill layer 129 (not shown)). The recess length L_{R130} of the recess R₁₃₀ may also include a second length portion L2 over the semiconductor module 120 (e.g., over the semiconductor die 140 and the molding material layer 127). In at least one embodiment, the recess length L_{R130} may be the sum of the first length portion L1 and the second length portion L2 (e.g., L_{R130}=L1+L2).

In at least one embodiment (e.g., where the recess R130 has an irregular shape), L1 may be a maximum distance from an edge of the recess R130 (outside the semiconductor module 120) perpendicular to a side of the semiconductor module 120 in the y-direction. L2 may be a maximum distance from an edge of the recess R130 (over the semiconductor module 120) perpendicular to a side of the semiconductor module 120 in the y-direction.

The first width portion W1 may be greater than, less than or equal to the first length portion L1. The second width portion W2 may be greater than, less than or equal to the second length portion L2. In at least one embodiment, the first width portion W1 may be greater than zero. In at least one embodiment, the first length portion L1 may be greater than zero. In at least one embodiment, the second width portion W2 of the recess width WR130 may be less than one-half the semiconductor module width W120 of the semiconductor module 120 (e.g., W2<0.5 W120). In at least one embodiment, the second length portion L2 of the recess length LR130 may be less than one-half the semiconductor module length L120 of the semiconductor module 120 (e.g., L2<0.5 L120).

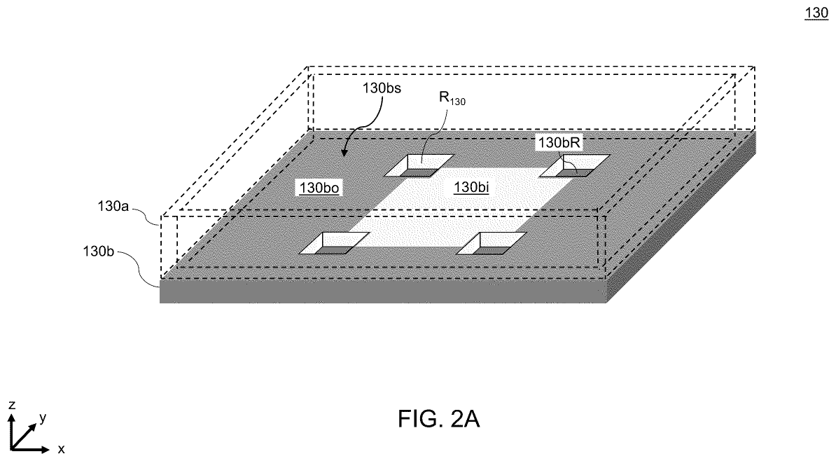

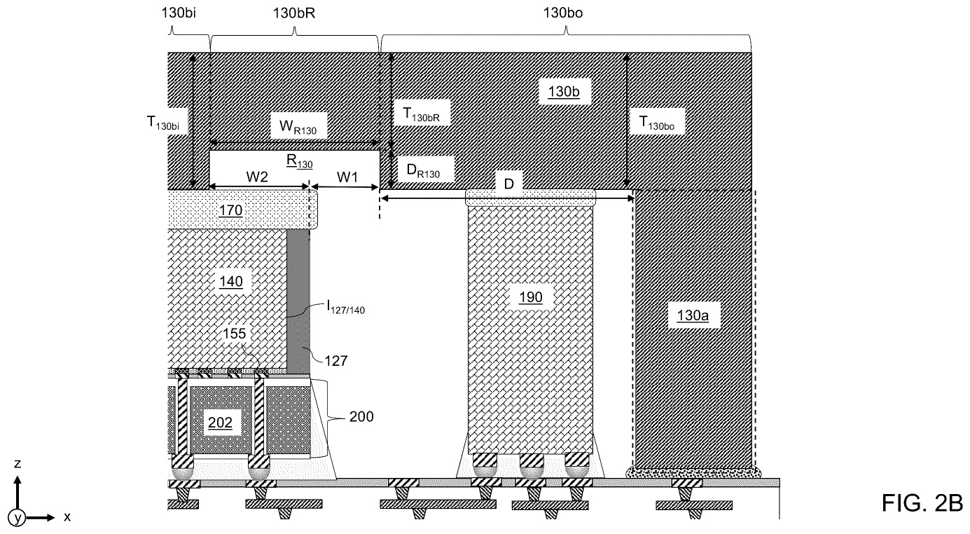

FIGS. 2A and 2B are detailed views of the recess R130 in the package lid plate portion 130b according to one or more embodiments. FIG. 2A is a perspective view of the package lid 130 including the recesses R130 in the package lid plate portion 130b according to one or more embodiments. FIG. 2B is a vertical cross-sectional view of a portion of the package lid plate portion 130b including a recess R130 according to one or more embodiments.

Referring to FIG. 2A, an outline of the package lid foot portion 130a is indicated by dashed lines for ease of understanding. As illustrated in FIG. 2A, the inner region 130bi of the package lid plate portion 130b may have a cross shape that extends between the recess regions 130bR of the package lid plate portion 130b. The outer region 130bo of the package lid plate portion 130b may surround the inner region 130bi and the recess regions 130bR of the package lid plate portion 130b in the x-direction and y-direction. The outer region 130bo of the package lid plate portion 130b may be formed around an entire periphery of the package lid plate portion 130b. The outer region 130bo of the package lid plate portion 130b may join the inner region 130bi of the package lid plate portion 130b between the recess regions 130bR of the package lid plate portion 130b.

Referring to FIG. 2B, the recess R₁₃₀ may be separated from the package lid foot portion 130a by a distance D. In at least one embodiment, the distance D may be greater than the recess width W_{R130} of the recess R₁₃₀ and greater than a recess length L_{R130} (not shown) of the recess R₁₃₀. The inner region 130bi of the package lid plate portion 130b may have a thickness T_{130bi}. The outer region 130bo of the package lid plate portion 130b may have a thickness T_{130bo} substantially the same as the thickness T_{130bi} of the inner region 130bi. That is, the package lid plate portion 130b may have a substantially uniform thickness outside of the recess region 130bR (e.g., T_{130bi}=T_{130bo}). In at least one embodiment, the outer region 130bo of the package lid plate portion 130b may have a thickness different than (e.g., less than or greater than) the thickness of the inner region 130bi (e.g., T_{130bi}≠T_{130bo}).

A depth D_{R130} of the recess R₁₃₀ may be less than the thickness T_{130bi} of the inner region 130bi and less than the thickness T_{130bo} of the outer region 130bo. The recess region 130bR of the package lid plate portion 130b may have a thickness T_{130bR}. In at least one embodiment, the thickness T_{130bR} of the recess region 130bR may be at least 50% of the thickness T_{130bi} of the inner region 130bi. In at least one embodiment, the thickness T_{130bR} of the recess region 130bR may be at least 50% of the thickness T_{130bo} of the outer region 130bo. In at least one embodiment, the thickness T_{130bR} of the recess region 130bR may be greater than the depth D_{R130} of the recess R₁₃₀. In at least one embodiment, the depth D_{R130} of the recess R₁₃₀ may be less than 50% of the thickness T_{130bR} of the recess region 130bR.

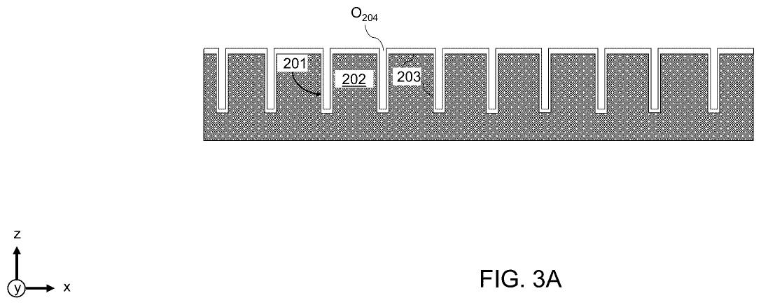

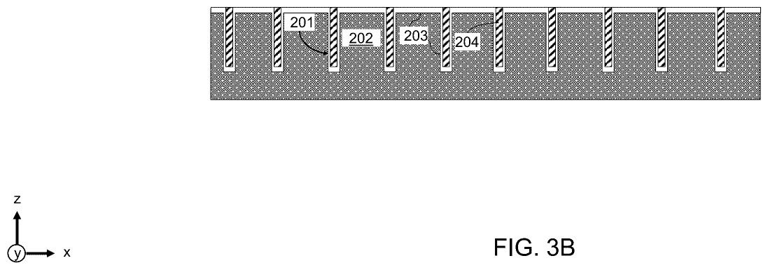

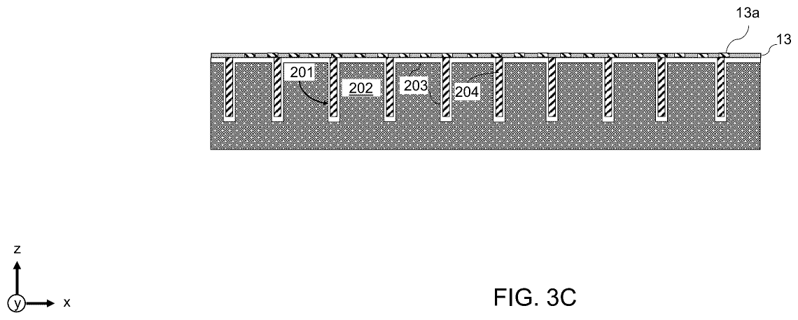

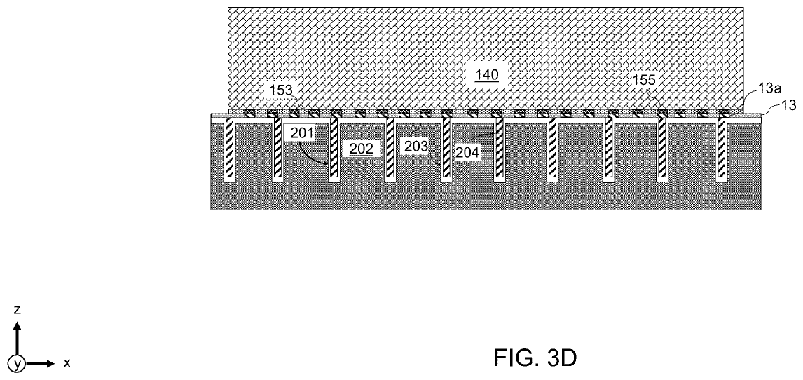

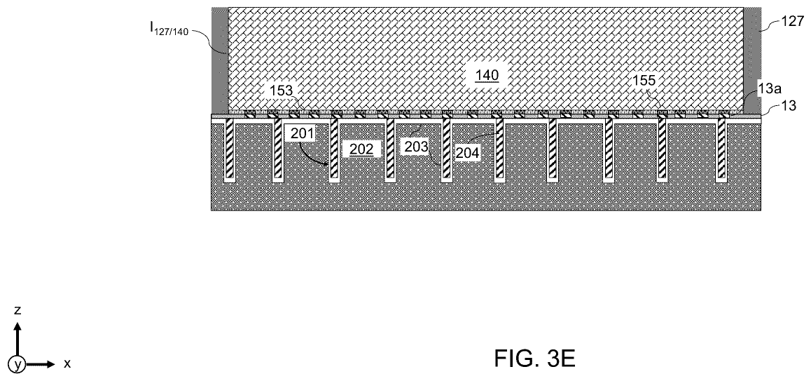

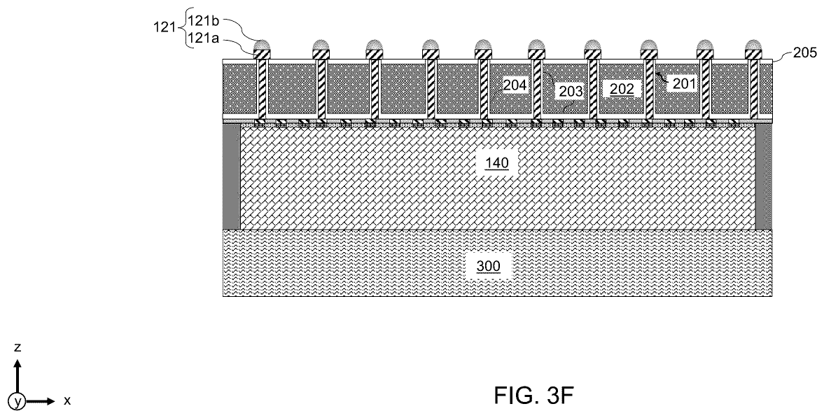

FIGS. 3A-3F illustrate various intermediate structures that may be formed during various stages in a method of forming the semiconductor module 120 according to one or more embodiments. FIG. 3A is a vertical cross-sectional view of an intermediate structure including the semiconductor material layer 202 according to one or more embodiments.

In the intermediate structure of FIG. 3A, the semiconductor material layer 202 may include, for example, a silicon wafer. The via cavities 201 may be formed in an upper portion of the silicon wafer. In one embodiment, the silicon wafer may be a commercially available silicon wafer having a diameter of 150 mm, 200 mm, 300 mm, or 450 mm.

An array of the via cavities 201 may be formed in the upper portion of the semiconductor material layer 202, for example, by a photolithograpic process. The photolithographic process may include, for example, forming an etch mask layer including a hard mask material (such as borosilicate glass) on the semiconductor material layer 202, patterning the etch mask layer with patterns of arrays of discrete openings, and transferring the pattern in the etch mask layer into an upper portion of the semiconductor material layer 202. The depth of the via cavities 201 in the intermediate structure may be in a range from 1 micron to 100 microns although lesser and greater depths may also be used. In one embodiment, the pattern of the array of via cavities 201 may have a two-dimensional periodicity over the semiconductor material layer 202.

The insulating liner 203 (e.g., silicon oxide) may then be formed on the sidewalls of the via cavities 201 and over the top surface of the semiconductor material layer 202 (e.g., silicon wafer). The insulating liner 203 may be formed by depositing (e.g., by CVD, PVD or other suitable deposition technique) a layer of insulating material on the semiconductor material layer 202. The insulating material may be deposited so as to be conformally formed on the sidewalls of the via cavities 201, so that openings O₂₀₄ bounded by the insulating liner 203 on the sidewalls of the via cavities 201 may be formed in the via cavities 201.

FIG. 3B is a vertical cross-sectional view of an intermediate structure including the TSVs 204 in the semiconductor material layer 202 according to one or more embodiments. The TSVs 204 may be formed in the openings O₂₀₄ in the via cavities 201 by depositing one or more layers of conductive material (e.g., metallic barrier material (TIN, TaN, WN, MON, TiC, TaC, WC, etc.), metallic fill material (Cu, Co, Ru, Mo, W, etc.), etc.) in the openings O₂₀₄.

The one or more layers of conductive material may be deposited, for example, by CVD, PVD or other suitable deposition technique. A planarization process such as a chemical mechanical polishing (CMP) process and/or a recess etch process may then be performed to remove any excess amount of the conductive material from above the horizontal plane including the top surface of the horizontally-extending portion of the insulating liner 203. The upper surface of the TSVs 204 may thereby be made to be substantially coplanar with the upper surface of the insulating liner 203.

FIG. 3C is a vertical cross-sectional view of an intermediate structure including the bonding layer 13 and upper bonding pads 13a according to one or more embodiments. The upper bonding pads 13a may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.) on the interposer 200. In particular, the one or more metal layers may be deposited on the upper surface of the insulating liner 203 and the upper surface of the TSVs 204. The metal layer(s) may then be patterned by a photolithographic process so as to form the upper bonding pads 13a in contact with the TSVs 204 in the interposer 200. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the upper bonding pads 13a may include an underbump metallurgy (UBM) layer stack. The order of material layers within the UBM layer stack may be selected such that solder material portions may be subsequently bonded to portions of the UBM layer stack. Layer stacks that may be used for the UBM layer stack include, but are not limited to, stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layer stack may be in a range from 5 microns to 60 microns, such as from 10 microns to 30 microns, although lesser and greater thicknesses may also be used. A photoresist layer may be applied over the UBM layer stack, and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the upper bonding pads 13a. In at least one embodiment, the upper bonding pads 13a may be arranged as a two-dimensional array, which may be a two-dimensional periodic array such as a rectangular periodic array.

The bonding layer 13 may then be formed on the insulating liner 203 and over the upper bonding pads 13a. The bonding layer 13 may be formed by depositing (e.g., by CVD, PVD or other suitable deposition technique) one or more layers of dielectric material such as silicon oxide, low-k dielectric materials such as carbon-doped oxides, extremely low-k dielectric materials such as porous carbon doped silicon dioxide, a combination thereof or other suitable material. The dielectric material may then be planarized (e.g., by wet etching, drying etching, etc.) until the upper bonding pads 13a are exposed. The bonding layer 13 may, thus, be formed to have an upper surface that is substantially coplanar with an upper surface of the upper bonding pads 13a.

FIG. 3D is a vertical cross-sectional view of an intermediate structure including the semiconductor die 140 according to one or more embodiments. The semiconductor die 140 may be placed on the bonding layer 13, for example, by using a electromechanical pick-and-place (PNP) machine. A hybrid bonding process may be performed to bond the semiconductor die 140 to the interposer 200. The hybrid bonding process may form, for example, a metal-metal bond between the die bonding pads 155 and the upper bonding pads 13a. The hybrid bonding process may also form, for example, an oxide-oxide bond between the die bonding layer 153 and the bonding layer 13. It should be noted that the hybrid bonding process may utilize less than all of the die bonding pads 155, less than all of the upper bonding pads 13a, less than all of the bonding layer 13 and less than all of the die bonding layer 153.

The hybrid bonding process may optionally include, for example, a surface preparation step in which a surface of the semiconductor die 140 and a surface of the bonding layer 13 are prepared by cleaning and removing any contaminants or oxides that could interfere with bonding. The surface preparation step may help to achieve optimal bonding quality. An alignment step may be performed in which the semiconductor die 140 and the interposer 200 are more precisely aligned to help ensure accurate positioning of the interconnects. The alignment step may be performed, for example, using alignment marks or an optical alignment system. Once aligned, the semiconductor die 140 and the interposer 200 may be brought into close contact. The bonding process may be performed at room temperature (room-temperature bonding) or at elevated temperatures (thermal bonding) depending on the specific bonding technique used.

In the bonding process, the die bonding layer 153 and the bonding layer 13 may be activated to form a chemical bond (e.g., oxide-oxide bond) at the atomic level. In at least one embodiment, oxide layers in the die bonding layer 153 and the bonding layer 13 may be brought into contact, allowing oxygen atoms to migrate therebetween and form covalent bonds. In at least one embodiment, elevated temperature and pressure may be applied to form the oxide-oxide bond. Concurrently with the formation of the oxide-oxide bond, a metal-metal bond may be formed between the metal layers of the die bonding pads 155 and the upper bonding pads 13a. In at least one embodiment, elevated temperature and pressure may be applied to form the metal-metal bond through diffusion or solid-state reactions.

FIG. 3E is a vertical cross-sectional view of an intermediate structure including the molding material layer 127 according to one or more embodiments. The molding material layer 127 may be formed by dispensing a liquid molding material (e.g., epoxy molding material) onto the intermediate structure of FIG. 3D by a suitable dispensing tool. The molding material layer 127 may be dispensed onto the intermediate structure so as to have a height greater than a height of the upper surface of the semiconductor dies 140.

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the bonding layer 13, a size of the semiconductor dies 140, etc.

In at least one embodiment, the molding material of the molding material layer 127 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the semiconductor dies 140. The low viscosity may also help to avoid the formation of voids in the molding material layer 127. In at least one embodiment, the molding material layer 127 when cured may be substantially free of voids.

After the molding material layer 127 has been adequately cured, the molding material layer 127 may be thinned (e.g., planarized) so as to make the upper surface of the molding material layer 127 to be substantially coplanar with the upper surface of the semiconductor dies 140. The molding material layer 127 may be planarized, for example, by grinding, chemical mechanical polishing (CMP) or other suitable planarization techniques.

FIG. 3F is a vertical cross-sectional view of an intermediate structure after the thinning (e.g., planarizing) of the semiconductor material layer 202 and forming the C4 bumps 121 according to one or more embodiments. After the thinning (e.g., planarizing) of the molding material layer 127, a carrier substrate 300 (e.g., carrier wafer) may be attached to an upper surface of the intermediate structure of FIG. 3E. The carrier substrate 300 may include, for example, a circular wafer or a rectangular wafer. The lateral dimensions (such as the diameter of a circular wafer or a side of a rectangular wafer) of the carrier substrate 300 may be in a range from 100 mm to 500 mm, such as from 200 mm to 400 mm, although lesser and greater lateral dimensions may also be used. The carrier substrate 300 may include a semiconductor substrate, an insulating substrate, or a conductive substrate. The carrier substrate 300 may be transparent or opaque. The thickness of the carrier substrate 300 may be sufficient to provide mechanical support to an array of interposers to be formed thereupon. For example, the thickness of the carrier substrate 300 may be in a range from 60 microns to 1 mm, although lesser and greater thicknesses may also be used.

An adhesive layer (not shown) may be applied to the top surface of the carrier substrate 300. In one embodiment, the carrier substrate 300 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

After the carrier substrate 300 is attached to the upper surface of the intermediate structure in FIG. 3E, the intermediate structure may be flipped (e.g., inverted). A backside surface of the semiconductor material layer 202 (e.g., silicon wafer) may then be thinned by performing a polishing process. In at least one embodiment, the semiconductor material layer 202 may be thinned by performing a CMP process. The polishing process may be performed until a bottom surface of the TSVs 204 is exposed.

The backside surface of the semiconductor material layer 202 may then be vertically recessed, for example, by performing an isotropic etch process that removes silicon selective to the insulating liner 203 and the TSVs 204. In an illustrative example, a wet etch process using potassium hydroxide may be performed to vertically recess the backside surface of the semiconductor material layer 202 by a vertical recess distance. The vertical recess distance may be in a range from 100 nm to 500 nm, although lesser and greater vertical recess distances may also be used.

The lower insulating layer 205 may then be formed on the recessed backside surface of the semiconductor material layer 202. The lower insulating layer 205 may be formed, for example, by depositing an insulating material such as silicon oxide on the recessed backside surface of the semiconductor material layer 202. The thickness of the lower insulating layer 205 may be about the same as, or may be greater than, the vertical recess distance of the backside silicon surface of the semiconductor material layer 202. A planarization process, such as a polishing process, may then be performed to remove portions of the lower insulating layer 205, and to make a surface of the lower insulating layer 205 to be coplanar with the bottom surface of the TSVs 204.

The plurality of C4 bumps 121 may then be formed so as to contact the bottom surface 204a of the TSVs 204. The C4 bumps 121 may be formed by forming the metal pillar 121a (e.g., copper pillar) on the bottom surface of the TSVs 204, for example, by an electroplating process. The solder bump 121b may then be formed on the metal pillar 121a by a suitable process (e.g., deposition, electroplating, etc.).

In at least one embodiment, a bonding pad (not shown) may be formed on the bottom surface of the TSVs 204, and the C4 bumps 121 may be formed on the bonding pad. In at least one embodiment, one or more underbump metallization (UBM) layers (not shown) may be formed on the bottom surface of the TSVs 204 (or the bonding pad, if present), and the metal pillar 121a may be formed on the UBM layers. That is, the C4 bump 121 may be formed so as to contact the TSVs 204 through the UBM layers and/or the bonding pad.

After the C4 bumps 121 are formed, the carrier substrate 300 may be detached from the intermediate structure. In some embodiments, the carrier substrate 300 and the adhesive layer (not shown) may be removed by backside grinding. Alternatively, the carrier substrate 300 includes an optically transparent material and the adhesive layer includes a light-to-heat conversion material, and irradiation through the carrier substrate 300 may be used to detach the carrier substrate 300. If the adhesive layer includes a thermally decomposable adhesive material, an anneal process or a laser irradiation may be used to detach the carrier substrate 300. A suitable clean process may be performed to remove residual portions of the adhesive layer.

In at least one embodiment, a plurality of the semiconductor modules 120 may be formed concurrently in a wafer-level process. In that case, after the forming of the C4 bumps 121, a singulation process may be performed in order to singulate the semiconductor modules 120. The singulation process may be performed, for example, by using a dicing saw to saw the interposer 200 (e.g., and the molding material 127 formed thereon) along dicing lines. The dicing lines may be located around the entire periphery of the semiconductor dies 140.

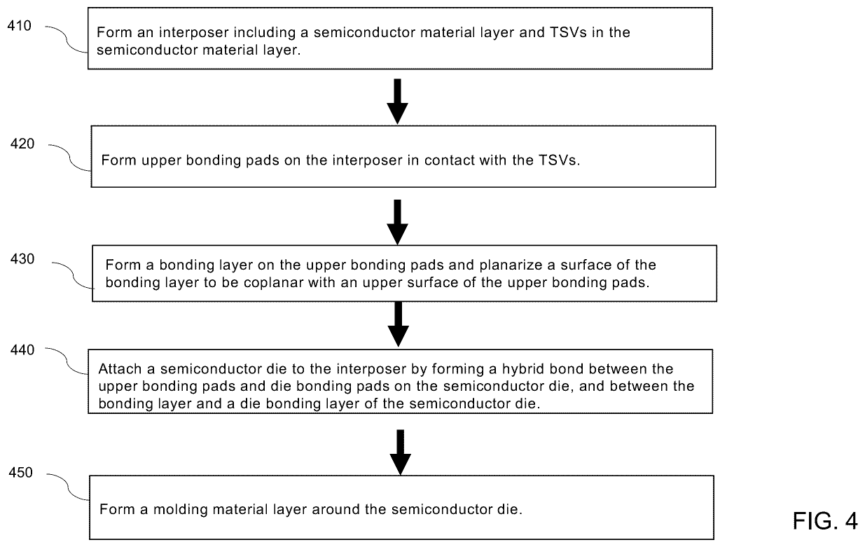

FIG. 4 is a flow chart illustrating a method of forming a semiconductor module according to one or more embodiments. With reference to FIGS. 3A, 3B, and 4, step 410 includes forming an interposer including a semiconductor material layer and TSVs in the semiconductor material layer. With reference to FIGS. 3C and 4, step 420 includes forming upper bonding pads on the interposer in contact with the TSVs. With reference to FIGS. 3C and 4, step 430 includes forming a bonding layer on the upper bonding pads and planarizing a surface of the bonding layer to be coplanar with an upper surface of the upper bonding pads. With reference to FIGS. 3D and 4, step 440 includes attaching a semiconductor die to the interposer by forming a hybrid bond between the upper bonding pads and die bonding pads on the semiconductor die, and between the bonding layer and a die bonding layer of the semiconductor die. With reference to FIGS. 3E and 4, step 450 includes forming a molding material layer around the semiconductor die.

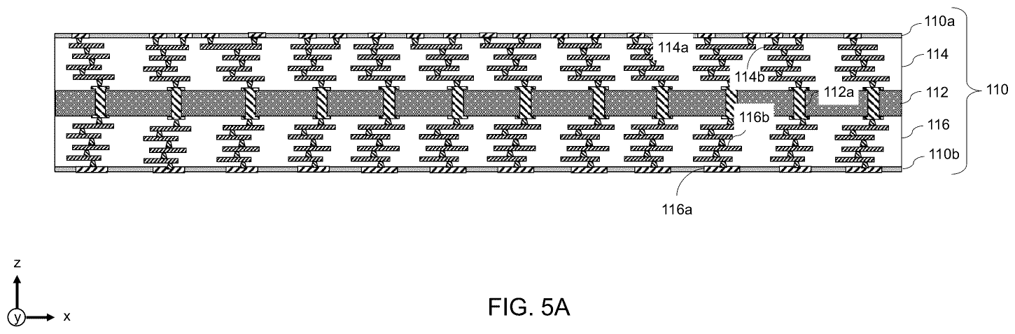

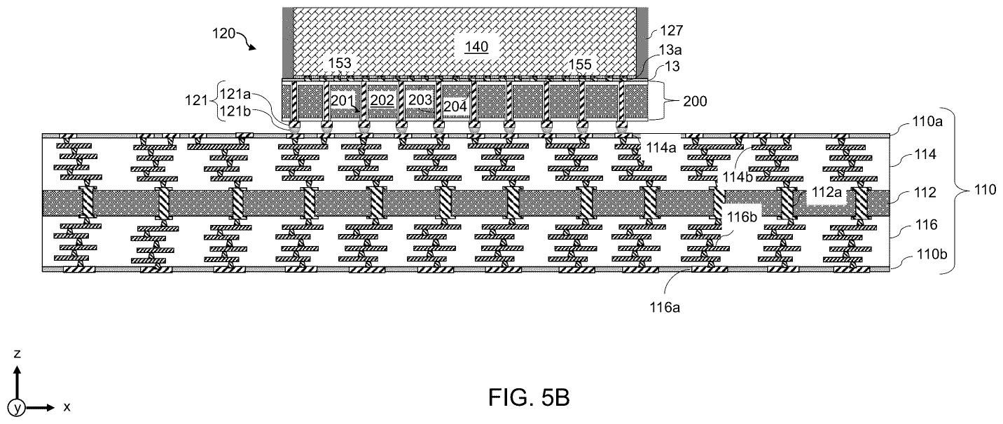

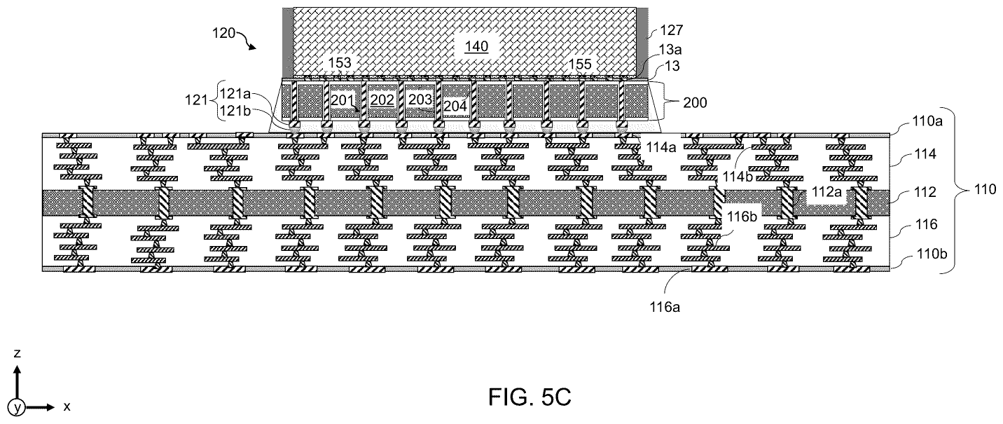

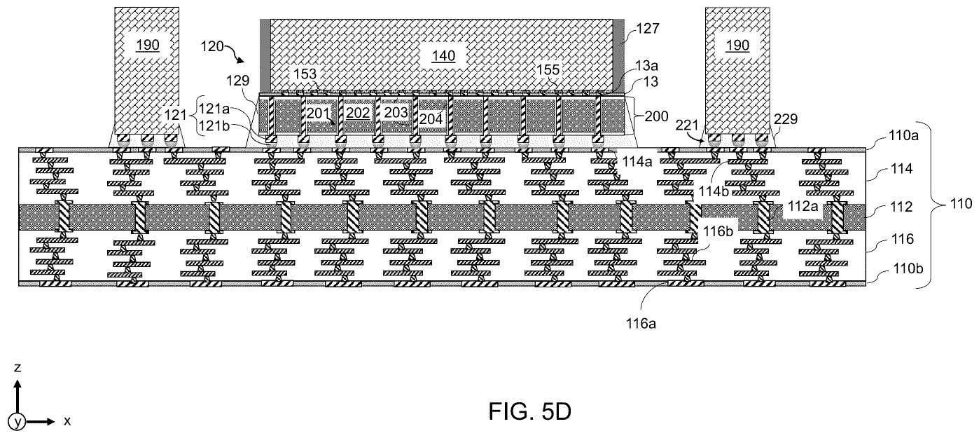

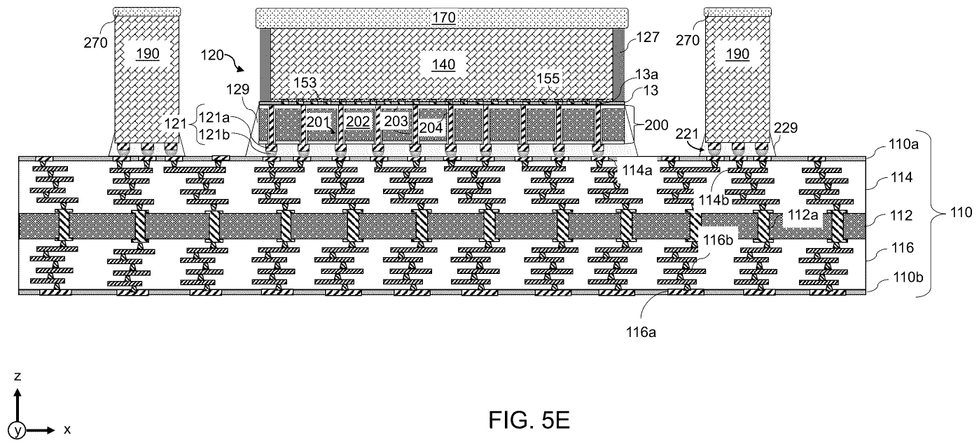

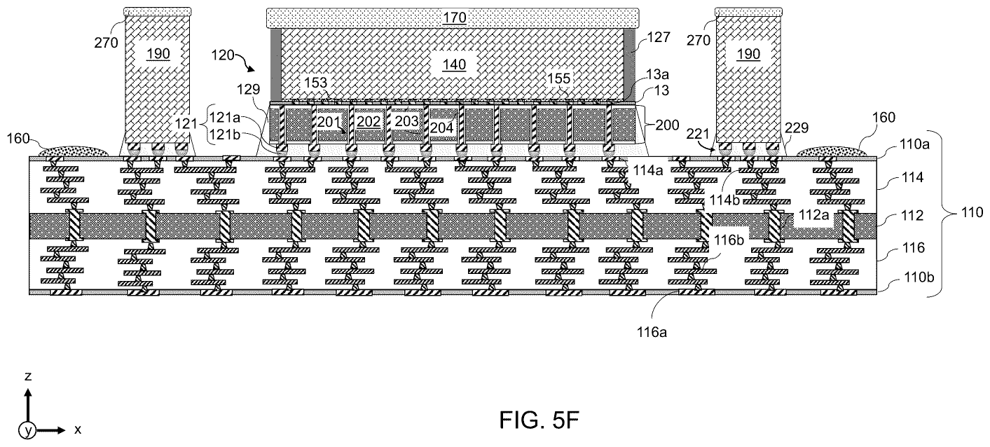

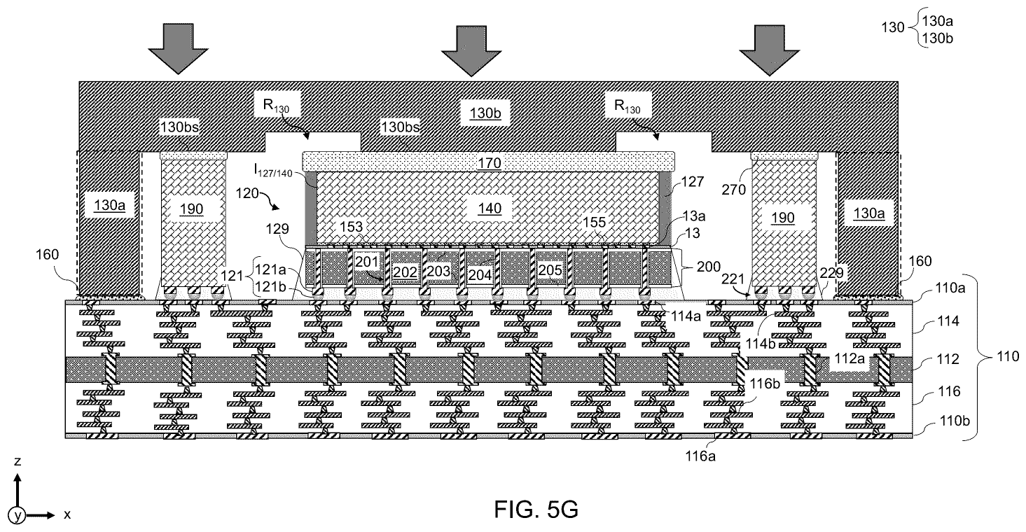

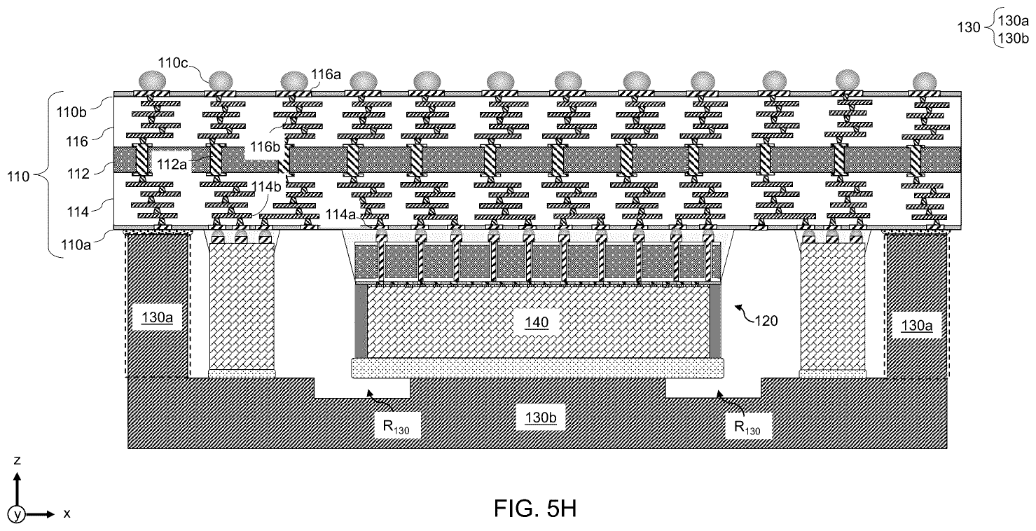

FIGS. 5A-5H illustrate various intermediate structures in a method of forming the package structure 100 according to one or more embodiments. FIG. 5A is a vertical cross-sectional view of an intermediate structure including the package substrate 110 having package substrate upper bonding pads 114a and package substrate lower bonding pads 116a, according to one or more embodiments.

The package substrate upper dielectric layer 114 may be built up on the core 112 in a series of deposition and photolithographic steps in which metal layers (e.g., forming metal traces and metal vias in the interconnect structures 114b) are alternatingly formed with layers of dielectric material. The package substrate lower dielectric layer 116 may similarly be built up on the core 112 in a series of deposition and photolithographic steps in which metal layers (e.g., forming metal traces and metal vias in the interconnect structures 116b) are alternatingly formed with layers of dielectric material.

The package substrate upper bonding pads 114a may then be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a may include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination or other suitable deposition technique.

As illustrated in FIG. 5A, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively. Alternatively, the package substrate upper passivation layer 110a and package substrate lower passivation layer 110b may be applied to have a thickness that is slightly greater than a thickness of the package substrate upper bonding pads 114a and package substrate lower bonding pads 116a, respectively. In that case, openings (not shown) may be formed (e.g., by etching (e.g., wet etching, dry etching, etc.) in a photolithographic process) in the package substrate upper passivation layer 110a and in the package substrate lower passivation layer 110b to expose the package substrate upper bonding pads 114a and package substrate lower bonding pads 116a, respectively.

FIG. 5B illustrates a vertical cross-sectional view of an intermediate structure in which the semiconductor module 120 may be attached to the package substrate 110, according to one or more embodiments. The semiconductor module 120 may be attached to the package substrate 110, for example, by a flip chip bonding (FCB) process. In the FCB process, the semiconductor module 120 may be positioned over the package substrate 110, for example, by an electromechanical pick-and-place (PNP) machine. The C4 bumps 121 on the semiconductor module 120 may be lowered onto the package substrate upper bonding pads 114a of the package substrate 110 and heated in order to collapse the C4 bumps 121 and bond the C4 bumps 121 to the package substrate upper bonding pads 114a.

FIG. 5C illustrates a vertical cross-sectional view of an intermediate structure in which the package underfill layer 129 may be formed on the package substrate 110 according to one or more embodiments. As illustrated in FIG. 5C, the package underfill layer 129 (e.g., epoxy-based polymeric material) may be dispensed (e.g., injected) onto the package substrate 110, under and around the semiconductor module 120 and around the C4 bumps 121. The package underfill layer 129 may then be cured, for example, in a box oven for duration in a range from 60 minutes to 120 minutes at a temperature in a range from 120° C. to 180° C. to provide the package underfill layer 129 with a sufficient stiffness and mechanical strength.

FIG. 5D illustrates a vertical cross-sectional view of an intermediate structure in which the optional adjacent dies 190 may be mounted on the package substrate 110 according to one or more embodiments. The adjacent dies 190 may be mounted on the package substrate 110 in a manner similar to the manner in which the semiconductor module 120 was attached to the package substrate 110. In particular, the adjacent dies 190 may be placed on the package substrate 110 such as by an electromechanical pick-and-place machine. The C4 bumps 221 on the adjacent dies 190 may then be bonded to the package substrate upper bonding pads 114a. The underfill layer 229 may then be formed on the package substrate 110 between the adjacent dies 190 and the package substrate 110 and around the C4 bumps 221.

FIG. 5E illustrates a vertical cross-sectional view of an intermediate structure including the TIM layer 170 and the TIM layer 270 according to one or more embodiments. A thermally conductive adhesive (not shown) may optionally be formed on an upper surface of the semiconductor module 120 and on an upper surface of the adjacent dies 190. The TIM layer 170 may be placed (e.g., dispensed) on the upper surface of the semiconductor module 120 and adhered to the upper surface of the semiconductor module 120 by the thermally conductive adhesive. The TIM layer 270 may be placed (e.g., dispensed) on the upper surface of the adjacent dies 190 and adhered to the upper surface of the adjacent dies 190 by the thermally conductive adhesive.

FIG. 5F illustrates a vertical cross-sectional view of an intermediate structure in which the adhesive layer 160 may be applied to the package substrate 110 according to one or more embodiments. The adhesive layer 160 may be dispensed onto the package substrate 110 with a dispensing tool (e.g., automated dispensing tool). The dispensing tool may dispense the adhesive layer 160 in a frame shape (e.g., the shape of the package lid foot portion 130a (e.g., see FIG. 1B)) around the semiconductor module 120 and the adjacent dies 190. At the time of application, the adhesive layer 160 may be sufficiently rigid so as to form a semi-solid bead on the surface of the package substrate 110. In at least one embodiment, a viscosity of the adhesive layer 160 at the time of application may be 50,000 centipoise (cp) or greater. Due in part to the viscosity of the adhesive layer 160, the shape of the semi-solid bead may remain substantially unchanged between the time of application by the dispensing tool and the later time of attaching the package lid foot portion 130a. The location of the frame shape of the adhesive layer 160 may correspond to a location of the package lid foot portion 130a (e.g., see FIG. 1B). A pressing of the package lid foot portion 130a onto the adhesive layer 160 may deform the adhesive layer 160.

FIG. 5G illustrates a vertical cross-sectional view of an intermediate structure in which the package lid 130 may be attached to (e.g., mounted on) the package substrate 110 according to one or more embodiments. As noted above, the package lid 130 may be composed of metal, ceramic or plastic and may be formed, for example, by milling using a computer numerical control (CNC) milling machine, or by molding or stamping the package lid 130 to include the recesses R₁₃₀. In at least one embodiment, the recesses R₁₃₀ may be formed in the package lid plate portion 130b at the time of forming the package lid 130. In at least one embodiment, the recesses R₁₃₀ may be formed in a separate step after forming the package lid 130. The recesses R₁₃₀ may be formed to have a precise location, size, shape, and depth based on several parameters. Those parameters may include, for example, the size, shape and location of the semiconductor module 120, the size, shape, location and thermal properties of the semiconductor dies 140 within the semiconductor module 120, and the size, shape, location and thermal properties of the optional adjacent dies 190.

To attach the package lid 130 to the package substrate 110, the semiconductor module 120 may be placed on a surface and the package lid 130 lowered down over the semiconductor module 120 and onto the package substrate 110. The package lid foot portion 130a may then be aligned with the adhesive 160 formed on the package substrate 110. The package lid 130 may then be pressed downward by applying a pressing force (indicated by directional arrows in FIG. 5G) down onto the package lid 130 so that the package lid foot portion 130a of the package lid 130 may contact the package substrate 110 through the adhesive 160. The pressing force may be applied substantially uniformly over each of the inner region 130bi, the recess region 130bR and the outer region 130bo of the package lid plate portion 130b.

Alternatively, the package lid 130 may be inverted (e.g., flipped) and placed on a surface (e.g., a flat surface), and the semiconductor module 120 on the package substrate 110 may be inverted and inserted into the package lid 130. The package substrate 110 and semiconductor module 120 may then be pressed by applying a pressing force down into the package lid 130 so that the package lid foot portion 130a may contact the package substrate 110 through the adhesive 160.

FIG. 5H illustrates a vertical cross-sectional view of an intermediate structure in which a plurality of solder balls 110c may be formed on the package substrate 110 according to one or more embodiments. The plurality of solder balls 110c may be formed on an exposed surface of the package substrate lower bonding pads 116a (e.g., through openings (not shown) in the package substrate lower passivation layer 110b). The solder balls 110c may be formed, for example, by an electroplating process. The solder balls 110c may be formed, for example, so as to be located under the package lid foot portion 130a and under the semiconductor module 120 and therebetween. The plurality of solder balls 110c may constitute a ball-grid array (BGA) that may allow the package structure 100 to be securely mounted (e.g., by surface mount technology (SMT)) on a substrate such as a printed circuit board and electrically coupled to the substrate.

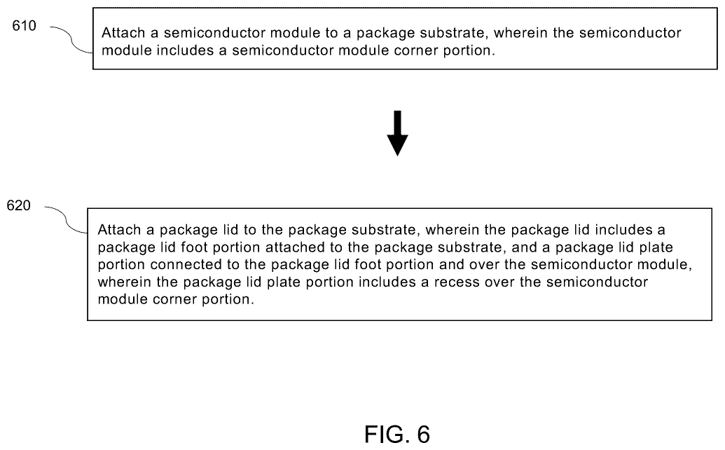

FIG. 6 is a flow chart illustrating a method of forming a package structure according to one or more embodiments. With reference to FIGS. 5B and 6, step 610 includes attaching a semiconductor module 120 to a package substrate 110, wherein the semiconductor module 120 includes a semiconductor module corner portion. With reference to FIGS. 5G and 6, step 630 includes attaching a package lid 130 to the package substrate 110, wherein the package lid 130 includes a package lid foot portion 130a attached to the package substrate 110, and a package lid plate portion 130b connected to the package lid foot portion 130a and over the semiconductor module 120, wherein the package lid plate portion 130b includes a recess R₁₃₀ over the semiconductor module corner portion.

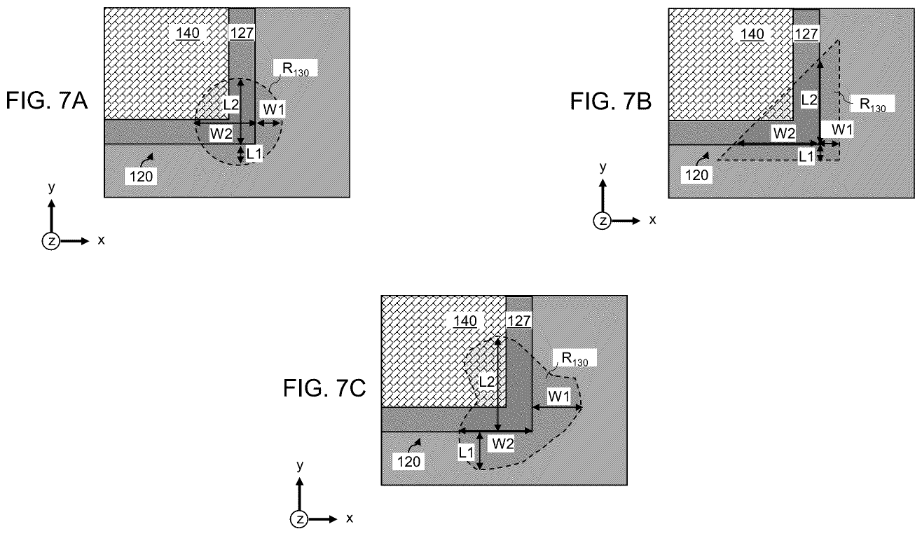

FIGS. 7A-7C are plan views of recesses R₁₃₀ having alternative designs in the package lid plate portion 130b according to one or more embodiments. FIG. 7A is a plan view of a recess R₁₃₀ having a first alternative design according to one or more embodiments. As illustrated in FIG. 7A, in the first alternative design, the recess R₁₃₀ may have a circular horizontal cross-sectional shape. The first width portion W1 (e.g., maximum width of the recess R₁₃₀ outside the semiconductor module 120 in the x-direction) and the second width portion W2 (e.g., maximum width of the recess R₁₃₀ over the semiconductor module 120 in the x-direction) may, therefore, be measured along a diameter of the circular-shape. The first length portion L1 (e.g., maximum length of the recess R₁₃₀ outside the semiconductor module 120 in the y-direction) and the second length portion L2 (e.g., maximum width of the recess R₁₃₀ over the semiconductor module 120 in the y-direction) may also be measured along a diameter of the circular-shape.

FIG. 7B is a plan view of recess R₁₃₀ having a second alternative design according to one or more embodiments. As illustrated in FIG. 7B, in the second alternative design, the recess R₁₃₀ may have a triangular shape. In at least one embodiment, the recess R₁₃₀ may have the shape of a right triangle where the right angle is substantially aligned with a corner of the semiconductor module 120. The second width portion W2 may, therefore, be measured along a sidewall of the semiconductor module 120 (e.g., along a sidewall of the molding material layer 127) in the x-direction. The first width portion W1 may be measured in a line with the second width portion W2. The second length portion L2 may similarly be measured along a sidewall of the semiconductor module 120 (e.g., along a sidewall of the molding material layer 127) in the y-direction. The first length portion L1 may be measured in a line with the second length portion L2.

FIG. 7C is a plan view of recess R₁₃₀ having a third alternative design according to one or more embodiments. As illustrated in FIG. 7C, in the third alternative design, the recess R₁₃₀ may have an arbitrary shape. In this embodiment, a location for measuring each of the first width portion W1 (e.g., maximum width of the recess R₁₃₀ outside the semiconductor module 120 in the x-direction), the second width portion W2 (e.g., maximum width of the recess R₁₃₀ over the semiconductor module 120 in the x-direction), the first length portion L1 (e.g., maximum length of the recess R₁₃₀ outside the semiconductor module 120 in the y-direction) and the second length portion L2 (e.g., maximum width of the recess R₁₃₀ over the semiconductor module 120 in the y-direction) may be individually determined based on the arbitrary shape of the recess R₁₃₀.

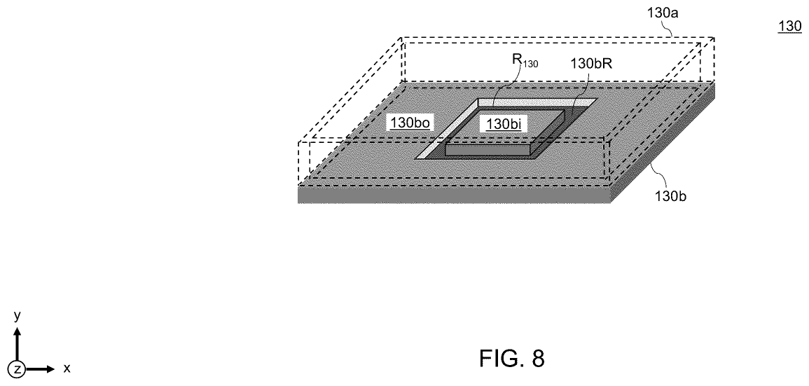

FIG. 8 is a perspective view of the package lid 130 including a recess R₁₃₀ having a fourth alternative design according to one or more embodiments. Similar to FIG. 2A, in FIG. 8, an outline of the package lid foot portion 130a is indicated by dashed lines for ease of understanding. As illustrated in FIG. 8, in the fourth alternative design, the recess R₁₃₀ may have a frame shape continuously formed around the inner region 130bi of the package lid plate portion 130b. In this embodiment, the recess R₁₃₀ may be formed over not only the semiconductor module corner portion 120c (see FIG. 1B) but over an entire outer periphery of the semiconductor module 120.

The recess region 130bR of the package lid plate portion 130b may also have a frame shape corresponding to the frame shape of the recess R₁₃₀. As illustrated in FIG. 8, the recess region 130bR of the package lid plate portion may completely separate the inner region 130bi of the package lid plate portion 130b from the outer region 130bo of the package lid plate portion 130b.

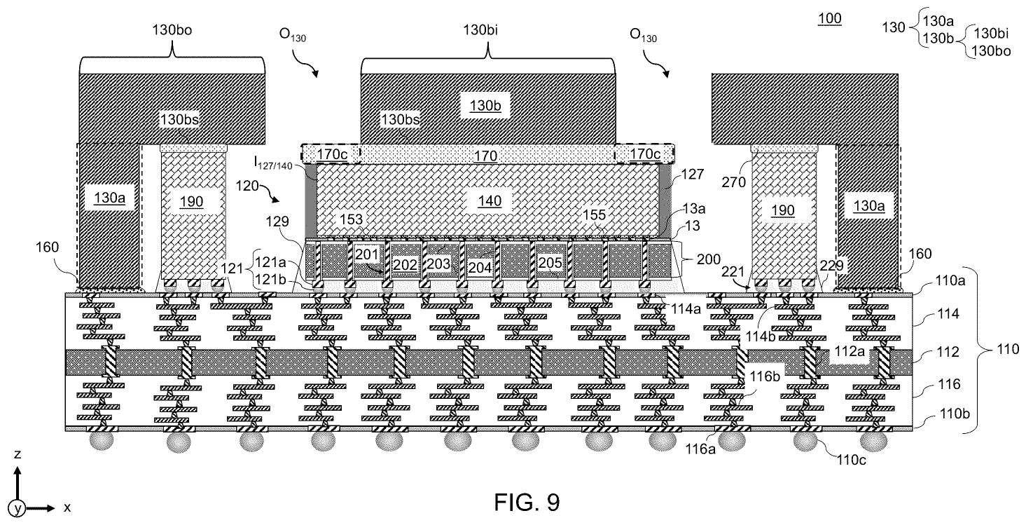

FIG. 9 is a detailed vertical cross-sectional view of the package structure 100 having a first alternative design according to one or more embodiments. As illustrated in FIG. 9, in the first alternative design of the package structure 100, the package lid plate portion 130b may include one or more openings O₁₃₀ instead of recesses R₁₃₀. Thus, in contrast to the original design in FIG. 1A, in the first alternative design, the package lid plate portion 130b may not include a recess region 130bR.

The openings O₁₃₀ may have a similar size, shape and location as the recesses R₁₃₀ described above. In particular, the openings O₁₃₀ may be located over the TIM layer corner portion 170c (see FIG. 1A) and over the semiconductor module corner portion 120c (see FIG. 1B). The openings O₁₃₀ may include a portion over the semiconductor module 120 and a portion outside the semiconductor module 120. The openings O₁₃₀ may have a width in the x-direction including the first width portion W1 and second width portion W2 (e.g., see FIG. 1C). The openings O₁₃₀ may have a length in the y-direction including the first length portion L1 and second length portion L2 (e.g., see FIG. 1C).

The openings O₁₃₀ may extend from an upper surface of the package lid plate portion 130b to a bottom surface 130bs of the package lid plate portion 130b. That is, a depth of the openings O₁₃₀ in the z-direction may be substantially the same as a thickness (e.g., T_{130bi} and/or T_{130bo}) of the package lid plate portion 130b. The openings O₁₃₀ may have a square shape (e.g., as illustrated in FIG. 1C), a circular shape (e.g., as illustrated in FIG. 7A), a triangular shape (e.g., as illustrated in FIG. 7B), an arbitrary shape (e.g., as illustrated in FIG. 7C), and so on. Other suitable shapes of the openings O₁₃₀ may also be used.

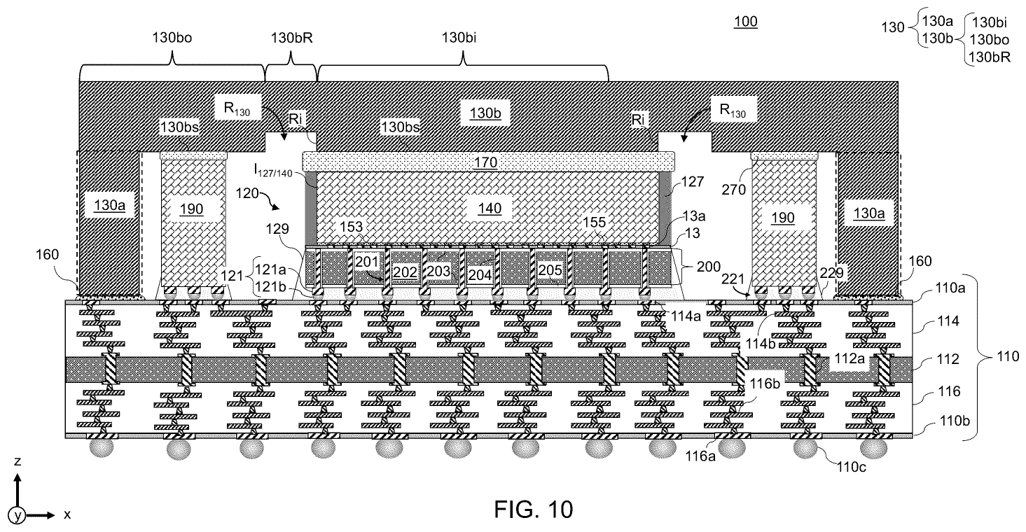

FIG. 10 is a detailed vertical cross-sectional view of the package structure 100 having a second alternative design according to one or more embodiments. As illustrated in FIG. 10, in the second alternative design, the recess R₁₃₀ may have a recess inner sidewall Ri substantially aligned with a sidewall of the semiconductor die 140. In at least one embodiment, the recess inner sidewall Ri may be substantially aligned with the die/molding material interface I_{127/140}. A hybrid bond stress may be reduced if the recess inner sidewall Ri is made to be close to the die/molding material interface I_{127/140}. In at least one embodiment, in the second alternative design, the recess R₁₃₀ may be formed over the molding material layer 127 but not the semiconductor die 140. In at least one embodiment, the semiconductor module corner portion 120c (see FIG. 1B) may include a corner of the molding material layer 127 but not a corner of the semiconductor die 140.

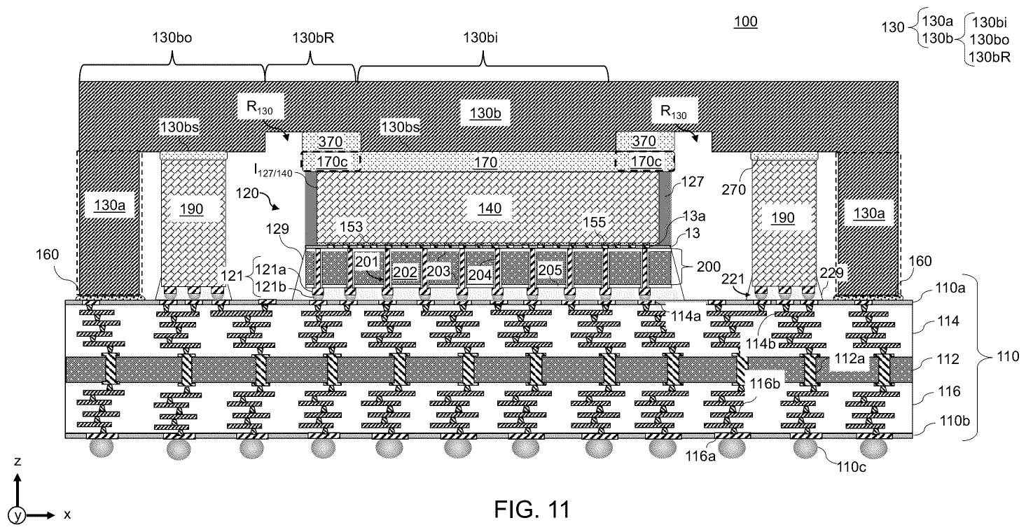

FIG. 11 is a detailed vertical cross-sectional view of the package structure 100 having a third alternative design according to one or more embodiments. As illustrated in FIG. 11, in the third alternative design, the package structure 100 may include an upper TIM layer 370 located in the recesses R₁₃₀. The upper TIM layer 370 may be substantially similar to the TIM layer 170. In particular, the upper TIM layer 370 may include substantially the same material as the TIM layer 170. In at least one embodiment, the upper TIM layer 370 may include a different material than the TIM layer 170. The upper TIM layer 370 may be located on the upper surface of the TIM layer corner portion 170c and have a shape (in the x-y plane) substantially the same as the shape of the TIM layer corner portion 170c.

The upper TIM layer 370 may be formed separately or together with the TIM layer 170. In at least one embodiment, the TIM layer 370 is integrally formed with the TIM layer 170 and constitutes a thickened portion of the TIM layer 170. The upper TIM layer 370 may be attached to a sidewall of the recesses R₁₃₀ by a thermally conductive adhesive layer.

Referring to FIGS. 1A-11, a package structure 100 may include a package substrate 110, a semiconductor module 120 on the package substrate 110 and including a semiconductor module corner portion 120c, and a package lid 130 on the package substrate 110 and over the semiconductor module 120, the package lid 130 including a package lid foot portion 130a attached to the package substrate 110, and a package lid plate portion 130b attached to the package lid foot portion 130a and over the semiconductor module 120, wherein the package lid plate portion 130b may include a recess R₁₃₀ over the semiconductor module corner portion 120c.

In one embodiment, the semiconductor module 120 may include an interposer 200, a semiconductor die 140 on the interposer 200, and a molding material layer 127 on the semiconductor die 140, wherein the semiconductor module corner portion 120c may include a corner of the semiconductor die 140 and a corner of the molding material layer 127. In one embodiment, the recess R₁₃₀ may have a recess width W_{R130} in a first direction and the recess width W_{R130} may include a first width portion W1 outside the semiconductor module and a second width portion W2 over the semiconductor module 120. In one embodiment, the second width portion W2 may be greater than the first width portion W1. In one embodiment, the semiconductor module 120 may have a semiconductor module width W₁₂₀ in the first direction, and the second width portion W2 may be less than one-half the semiconductor module width W₁₂₀. In one embodiment, the recess R₁₃₀ may have a recess length L_{R130} in a second direction perpendicular to the first direction and the recess length L_{R130} may include a first length portion L1 outside the semiconductor module 120 and a second length portion L2 over the semiconductor module 120. In one embodiment, the second length portion L2 may be greater than the first length portion L1. In one embodiment, the semiconductor module 120 may have a semiconductor module length L₁₂₀ in the second direction, and the second length portion L2 may be less than one-half the semiconductor module length L₁₂₀. In one embodiment, the recess R₁₃₀ may include one of a square shape, a circular shape or a triangular shape. In one embodiment, a depth D_{R130} of the recess R₁₃₀ may be less than a thickness T_{130bi} of the package lid plate portion 130b. In one embodiment, the package structure 100 may further include a thermal interface material (TIM) layer 170 on the semiconductor module 120, wherein the package lid plate portion 130b contacts the TIM layer 170. In one embodiment, the TIM layer 170 may include a TIM layer corner portion 170c on the semiconductor module corner portion 120c and the recess R₁₃₀ may be over the TIM layer corner portion 170c. In one embodiment, the package structure 100 may further include an adjacent die 190 on the package substrate 110 between the semiconductor module 120 and the package lid foot portion 130a and electrically coupled to the semiconductor module 120 through the package substrate 110, and an adjacent thermal interface material (TIM) layer on the adjacent die 190, wherein the package lid plate portion 130b contacts the adjacent TIM layer 270.

Referring again to FIGS. 1A-11, a method of making a package structure 100 may include attaching a semiconductor module 120 to a package substrate 110, wherein the semiconductor module 120 may include a semiconductor module corner portion 120c, and attaching a package lid 130 to the package substrate 110, wherein the package lid 130 may include a package lid foot portion 130a attached to the package substrate 110, and a package lid plate portion 130b connected to the package lid foot portion 130a and over the semiconductor module 120, wherein the package lid plate portion 130b may include a recess R₁₃₀ over the semiconductor module corner portion 120c.

In one embodiment, the method may further include forming the semiconductor module 120, wherein the forming of the semiconductor module 120 may include attaching a semiconductor die 140 to an interposer 200 by forming a hybrid bond between the semiconductor die 140 and the interposer 200, and forming a molding material layer 127 on the semiconductor die 140, wherein the semiconductor module corner portion 120c may include a corner of the semiconductor die 140 and a corner of the molding material layer 127. In one embodiment, attaching of the package lid 130 to the package substrate 110 may include positioning a portion of the recess R130 over the semiconductor module corner portion 120c and a portion of the recess R₁₃₀ outside the semiconductor module corner portion 120c. The method may further include forming a thermal interface material (TIM) layer 170 on the semiconductor module 120, and forming an adhesive layer 160 on the package substrate 110, wherein the attaching of the package lid 130 to the package substrate 110 may include pressing the package lid plate portion 130b onto the TIM layer 170 and attaching the package lid foot portion 130a to the package substrate 110 through the adhesive layer 160. In one embodiment, the forming of the TIM layer 170 may include positioning a TIM layer corner portion 170c of the TIM layer 170 on the semiconductor module corner portion 120c, and the attaching of the package lid 130 to the package substrate 110 may include positioning the recess R130 over the TIM layer corner portion 170c.

Referring again to FIGS. 1A-11, a package structure 100 may include a package substrate 110, a semiconductor module 120 on the package substrate 110 and including a semiconductor module corner portion 120c, and a package lid 130 on the package substrate 110 and over the semiconductor module 120, wherein the package lid 130 may include a package lid foot portion 130a attached to the package substrate 110, and a package lid plate portion 130b attached to the package lid foot portion 130a and over the semiconductor module 120, wherein the package lid plate portion 130b may include an opening O₁₃₀ over the semiconductor module corner portion 120c and the opening O₁₃₀ may extend from an upper surface of the package lid plate portion 130b to a bottom surface of the package lid plate portion 130b.

In one embodiment, the opening O₁₃₀ may include one of a square shape, a circular shape or a triangular shape.

The various embodiments of the present disclosure may be used to improve (e.g., optimize) a structure of the package lid so as to reduce a stress concentration in the interposer. Various embodiments may include a package lid 130 having one or more recesses R₁₃₀ (e.g., a recessed portion such as a lid cave, stress relief cave, etc.). Recesses may be located in the package lid 130 at a corner of a semiconductor die 140 on the semiconductor module 120. The one or more embodiments may help to improve (e.g., optimize) a structure of the package lid so as to reduce a stress concentration in the interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a semiconductor module on the package substrate and including a semiconductor module corner portion; and
a package lid on the package substrate and over the semiconductor module, the package lid comprising:
a package lid foot portion attached to the package substrate; and
a package lid plate portion attached to the package lid foot portion and over the semiconductor module, wherein the package lid plate portion includes a recess over the semiconductor module corner portion.

2. The package structure of claim 1, wherein the semiconductor module comprises:
an interposer;
a semiconductor die on the interposer; and
a molding material layer on the semiconductor die, wherein the semiconductor module corner portion includes a corner of the semiconductor die and a corner of the molding material layer.

3. The package structure of claim 2, wherein the recess includes a recess width in a first direction and the recess width includes a first width portion outside the semiconductor module and a second width portion over the semiconductor module.

4. The package structure of claim 3, wherein the second width portion is greater than the first width portion.

5. The package structure of claim 3, wherein the semiconductor module has a semiconductor module width in the first direction, and the second width portion is less than one-half the semiconductor module width.

6. The package structure of claim 3, wherein the recess includes a recess length in a second direction perpendicular to the first direction and the recess length includes a first length portion outside the semiconductor module and a second length portion over the semiconductor module.

7. The package structure of claim 6, wherein the second length portion is greater than the first length portion.

8. The package structure of claim 7, wherein the semiconductor module has a semiconductor module length in the second direction, and the second length portion is less than one-half the semiconductor module length.

9. The package structure of claim 1, wherein the recess comprises one of a square shape, a circular shape or a triangular shape.

10. The package structure of claim 1, wherein a depth of the recess is less than a thickness of the package lid plate portion.

11. The package structure of claim 1, further comprising:
a thermal interface material (TIM) layer on the semiconductor module, wherein the package lid plate portion contacts the TIM layer.

12. The package structure of claim 10, wherein the TIM layer comprises a TIM layer corner portion on the semiconductor module corner portion and the recess is over the TIM layer corner portion.

13. The package structure of claim 1, further comprising:
an adjacent die on the package substrate between the semiconductor module and the package lid foot portion and electrically coupled to the semiconductor module through the package substrate; and
an adjacent thermal interface material (TIM) layer on the adjacent die, wherein the package lid plate portion contacts the adjacent TIM layer.

14. A method of making a package structure, the method comprising:
attaching a semiconductor module to a package substrate, wherein the semiconductor module includes a semiconductor module corner portion; and
attaching a package lid to the package substrate, wherein the package lid comprises:
a package lid foot portion attached to the package substrate; and
a package lid plate portion connected to the package lid foot portion and over the semiconductor module, wherein the package lid plate portion includes a recess over the semiconductor module corner portion.

15. The method of claim 14, further comprising:
forming the semiconductor module, wherein the forming of the semiconductor module comprises:
attaching a semiconductor die to an interposer by forming a hybrid bond between the semiconductor die and the interposer; and
forming a molding material layer on the semiconductor die, wherein the semiconductor module corner portion includes a corner of the semiconductor die and a corner of the molding material layer.

16. The method of claim 15, wherein the attaching of the package lid to the package substrate comprises positioning a portion of the recess over the semiconductor module corner portion and a portion of the recess outside the semiconductor module corner portion.

17. The method of claim 14, further comprising:
forming a thermal interface material (TIM) layer on the semiconductor module; and
forming an adhesive layer on the package substrate, wherein the attaching of the package lid to the package substrate comprises pressing the package lid plate portion onto the TIM layer and attaching the package lid foot portion to the package substrate through the adhesive layer.

18. The method of claim 17, wherein the forming of the TIM layer comprises positioning a TIM layer corner portion of the TIM layer on the semiconductor module corner portion, and the attaching of the package lid to the package substrate comprises positioning the recess over the TIM layer corner portion.

19. A package structure, comprising:
a package substrate;
a semiconductor module on the package substrate and including a semiconductor module corner portion; and
a package lid on the package substrate and over the semiconductor module, wherein the package lid comprises:
a package lid foot portion attached to the package substrate; and
a package lid plate portion attached to the package lid foot portion and over the semiconductor module, wherein the package lid plate portion includes an opening over the semiconductor module corner portion and the opening extends from an upper surface of the package lid plate portion to a bottom surface of the package lid plate portion.

20. The package structure of claim 19, wherein the opening comprises one of a square shape, a circular shape or a triangular shape.
